(19) United States
(12) Patent Application Publication
(10) Pub. No.: US 2025/0301885 A1
(43) Pub. Date: Sep. 25, 2025

(54) DISPLAY PANEL, DISPLAY APPARATUS, AND METHOD FOR MANUFACTURING DISPLAY PANEL

(71) Applicants: Hefei Visionox Technology Co., Ltd., Hefei (CN); Visionox Technology Inc., Jiangsu (CN)

(72) Inventors: Zhengkui DONG, Hefei (CN); Yuan YAO, Hefei (CN); Zhiwei ZHOU, Hefei (CN); Deng GAO, Hefei (CN); Xuejing ZHU, Hefei (CN); Haohan ZHANG, Hefei (CN); Zengqiang XIA, Hefei (CN); Xiujian ZHU, Hefei (CN)

(73) Assignees: Hefei Visionox Technology Co., Ltd., Hefei (CN); Visionox Technology Inc., Jiangsu (CN)

(21) Appl. No.: 18/937,287

(22) Filed: Nov. 5, 2024

Related U.S. Application Data
(63) Continuation of application No. PCT/CN2024/102783, filed on Jun. 30, 2024.

(30) Foreign Application Priority Data
Mar. 20, 2024 (CN) 202410337563.3

(51) Int. Cl. H10K 59/80; H10K 59/12; H10K 59/122

(52) U.S. Cl. CPC H10K 59/873; H10K 59/1201; H10K 59/122

(57) ABSTRACT

A display panel, a display apparatus, and a method for manufacturing a display panel. The display panel includes: a base plate; an isolation structure located at one side of the base plate; a plurality of isolation openings encircled by the isolation structure; a light-emitting layer located at one side of the base plate and including a plurality of light-emitting units arranged at intervals, the light-emitting units being at least partially located in the isolation openings, respectively; and a first encapsulation layer including a plurality of encapsulation portions for encapsulating the light-emitting units, in which an orthographic projection of an encapsulation portion corresponding to at least one of the light-emitting units on the base plate at least partially overlaps an orthographic projection of an encapsulation portion corresponding to at least one of the light-emitting units adjacent to the at least one light-emitting unit on the base plate.

### CROSS REFERENCE TO RELATED APPLICATION

The present application is a continuation application of International Application No. PCT/CN2024/102783, filed on Jun. 30, 2024, which claims priority to Chinese Patent Application No. 202410337563.3 filed on Mar. 20, 2024, both of which are incorporated herein by reference in their entireties.

### TECHNICAL FIELD

The present application relates to the field of display, and particularly to a display panel, a display apparatus, and a method for manufacturing a display panel.

### BACKGROUND

Planar display apparatus based on Organic Light Emitting Diode (OLED) and Light Emitting Diode (LED), etc., are widely used in cell phones, TVs, notebook computers, desktop computers and other consumer electronic products due to their high image quality, power saving, thin body and wide range of applications, and have become the mainstream of the display apparatus.

However, the using performance of the current OLED display products needs to be improved.

### SUMMARY

Embodiments of the present application provide a display panel, a display apparatus, and a method for manufacturing a display panel, aiming to improve the using performance of the OLED display products.

Some embodiments of a first aspect of the present application provide a display panel including: a base plate; an isolation structure located at one side of the base plate; a plurality of isolation openings encircled by the isolation structure; a light-emitting layer located at one side of the base plate and including a plurality of light-emitting units arranged at intervals, the plurality of light-emitting units being at least partially located in the plurality of isolation openings, respectively; and a first encapsulation layer including a plurality of encapsulation portions for encapsulating the plurality of light-emitting units, in which an orthographic projection of an encapsulation portion corresponding to at least one of the plurality of light-emitting units on the base plate at least partially overlaps an orthographic projection of an encapsulation portion corresponding to at least one of the light-emitting units adjacent to the at least one light-emitting unit on the base plate.

Some other embodiments of the first aspect of the present application provide a display panel including: a base plate; an isolation structure located at one side of the base plate and including a top surface away from the base plate; a plurality of isolation openings encircled by the isolation structure; a light-emitting layer located at one side of the base plate and including a plurality of light-emitting units, the plurality of light-emitting units being at least partially located in the plurality of isolation openings, respectively; and a first encapsulation layer including a plurality of encapsulation portions for encapsulating the plurality of light-emitting units, in which the plurality of encapsulation portions are located at a side of the plurality of light-emitting units away from the base plate, the plurality of encapsulation portions further cover a sidewall of the isolation structure towards the plurality of isolation openings and extend to a side of the isolation structure away from the base plate, and form a plurality of covering segments at the side of the isolation structure away from the base plate, the covering segment of at least one of the plurality of encapsulation portions includes a first area and a second area, and along a thickness direction of the base plate, a distance from the first area to the top surface is different from a distance from the second area to the top surface.

Some embodiments of a second aspect of the present application provide a display apparatus including the display panel according to any of the above embodiments.

Some embodiments of a third aspect of the present application further provide a method for manufacturing a display panel, including: forming an isolation structure on a base plate; forming a plurality of isolation openings encircled by the isolation structure and comprising a plurality of first isolation openings and a plurality of second isolation openings; forming a plurality of first light-emitting units and a plurality of first encapsulation portions at least partially arranged in the plurality of first isolation openings, respectively; and forming a plurality of second light-emitting units and a plurality of second encapsulation portions at least partially arranged in the plurality of second isolation openings, respectively, and the plurality of second encapsulation portions partially extending over the plurality of first encapsulation portions.

The display panel according to the embodiments of the present application includes the base plate, the isolation structure, the isolation openings, the light-emitting layer, and the first encapsulation layer. The isolation structure is arranged on the base plate and encircles the plurality of isolation openings, so as to separate the light-emitting layer to form the light-emitting units that are disconnected from each other, thereby reducing the crosstalk of carriers in the light-emitting layer and improving the display effect of the display panel, and the light-emitting units are prepared without a fine mask plate, which can reduce the development and use of the fine mask plate and reduce the preparation cost. The first encapsulation layer includes the encapsulation portions for encapsulating the light-emitting units, and the encapsulation portions can provide encapsulation protection for the light-emitting units, and thus the effect of water and oxygen intrusion on the yield of the light-emitting units is reduced. The orthographic projection of the encapsulation portion corresponding to at least one of the light-emitting units on the base plate at least partially overlaps the orthographic projection of the encapsulation portion corresponding to at least one of the light-emitting units adjacent to the at least one light-emitting unit on the base plate, so that the distribution area of the encapsulation portion is great, and a portion of the adjacent encapsulation portions overlap, which can increase the distribution area of the encapsulation portion and improve the encapsulation effect. Moreover, at least one of the encapsulation portions is covered by other encapsulation portions, the relative position between the covered encapsulation portion and the isolation structure is more stable, and the covered encapsulation portion is less likely to be damaged, which can further improve the yield and the using performance of the display panel.

### BRIEF DESCRIPTION OF THE DRAWINGS

Other features, objects, and advantages of the present application will be more apparent from reading the following detailed description of non-limiting embodiments with reference to the accompanying drawings, in which the same or similar reference numerals denote the same or similar features, and the accompanying drawings are not drawn to actual scale.

FIG. 1 shows a schematic structural diagram of a display panel according to an embodiment of the present application;

FIG. 2 shows a partially enlarged schematic structural diagram at M1 in FIG. 1 in an example;

FIG. 3 shows a cross-sectional view at A-A in FIG. 2 in an example;

FIG. 4 shows a cross-sectional view at A-A in FIG. 2 in another example;

FIG. 5 shows a partially enlarged schematic structural diagram at M1 in FIG. 1 in another example;

FIG. 6 shows a cross-sectional view at B-B in FIG. 2 in an example;

FIG. 7 shows a cross-sectional view at B-B in FIG. 2 in another example;

FIG. 8 shows a partially enlarged schematic structural diagram at M1 in FIG. 1 in yet another example;

FIG. 9 shows a partially enlarged schematic structural diagram at M1 in FIG. 1 in yet another example;

FIG. 10 shows a cross-sectional view at C-C in FIG. 8 in an example;

FIG. 11 shows a partially enlarged schematic structural diagram at M1 in FIG. 1 in yet another example;

FIG. 12 shows a cross-sectional view at D-D in FIG. 2 in an example;

FIG. 13 shows a partially enlarged schematic structural diagram of FIG. 12 in an example;

FIG. 14 shows a partially enlarged schematic structural diagram of FIG. 12 in another example;

FIG. 15 shows a cross-sectional view at D-D in FIG. 2 in another example;

FIG. 16 shows a partially enlarged schematic structural diagram of FIG. 15 in an example;

FIG. 17 shows a partially enlarged schematic structural diagram of FIG. 2 in an example;

FIG. 18 shows a cross-sectional view at A-A in FIG. 2 in another example;

FIG. 19 shows a cross-sectional view at A-A in FIG. 2 in another example;

FIG. 20 shows a cross-sectional view at A-A in FIG. 2 in another example;

FIG. 21 shows a cross-sectional view at A-A in FIG. 2 in another example;

FIG. 22 shows a cross-sectional view at A-A in FIG. 2 in another example;

FIG. 23 shows a cross-sectional view at A-A in FIG. 2 in another example;

FIG. 24 shows a flow chart of a method for manufacturing a display panel according to an embodiment of the present application.

### REFERENCE NUMERALS

10, display panel;
100, base plate;
200, isolation structure; 201, top surface; 210, first layer; 220, second layer; 230, third layer; 240, isolation opening; 250, light-transmitting opening;
300, light-emitting layer; 310, light-emitting unit; 311, first light-emitting unit; 312, second light-emitting unit; 313, third light-emitting unit; 320, redundant unit;
400, first encapsulation layer; 401, encapsulation portion; 401a, covering segment; 410, first encapsulation portion; 411, first segment; 412, second segment; 412a, first surface; 412b, second surface; 412c, first side surface; 420, second encapsulation portion; 421, third segment; 422, fourth segment; 422a, first sub-segment; 422a1, first body portion; 422a2, connecting portion; 422b, second sub-segment; 430, third encapsulation portion; 431, fifth segment; 432, sixth segment; 432a, third sub-segment; 432b, fourth sub-segment; 432c, fifth sub-segment;
402, second encapsulation layer; 403, third encapsulation layer;
500, second electrode layer; 510, second electrode; 520, redundant electrode;
600, pixel defining layer; 610, pixel defining portion; 620, pixel opening; 630, first electrode;
AA1, main display area; AA2, functional display area;
QA, overlapping area; QB, hollow area;
Q1, first gap; Q2, second gap; Q3, third gap; Q4, first spacing;
D1, first width; D2, second width; d1, first sub-width; d2, second sub-width; d3, third sub-width; d4, fourth sub-width; d5, fifth sub-width;
X, first direction; Y, second direction; Z, thickness direction.

### DETAILED DESCRIPTION

Features and exemplary embodiments of various aspects of the present application will be described in detail below, and in order to make the purposes, technical solutions and advantages of the present application clearer, the present application is described in further detail below in connection with the accompanying drawings and specific embodiments. It should be understood that the specific embodiments described herein are configured only to explain the present application, but not to limit the present application. For those skilled in the art, the present application can be implemented without some of these specific details. The following description of the embodiments is merely to provide a better understanding of the present application by illustrating examples of the present application.

It should be understood that when describing the structure of a component, if a layer/area is described as being located “above” or “on” another layer/area, it may mean that the layer/area is located directly above the other layer/area, or that other layers/areas are included between the layer/area and the other layer/area. Moreover, if the component is turned over, the layer/area will be “below” or “under” the other layer/area.

The embodiments of the present application provide a display panel 10, a display apparatus, and a method for manufacturing the display panel 10, and various embodiments of which will be described below in connection with the accompanying drawings.

The embodiments of the present application provide a display panel 10, which may be an Organic Light Emitting Diode (OLED) display panel 10.

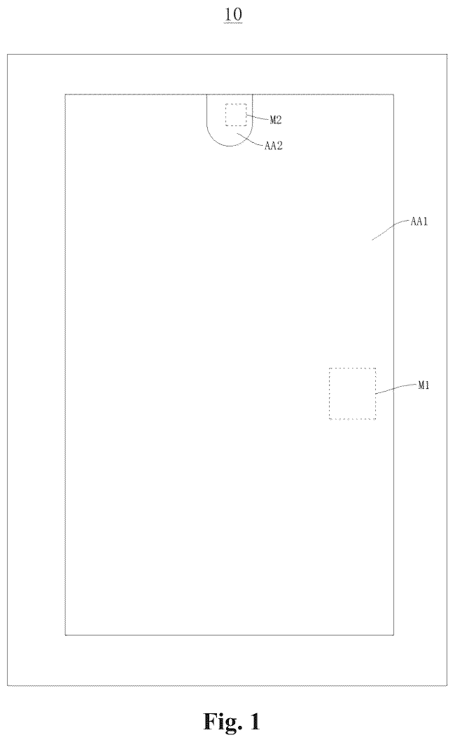

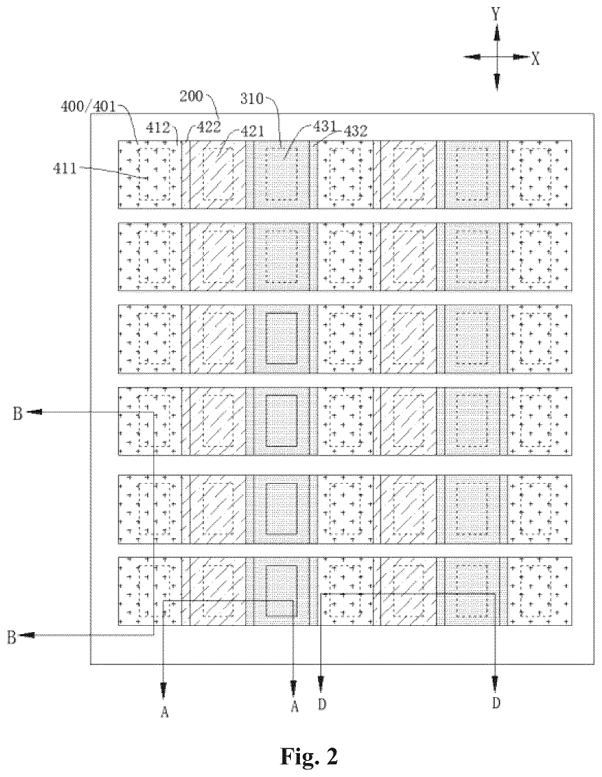

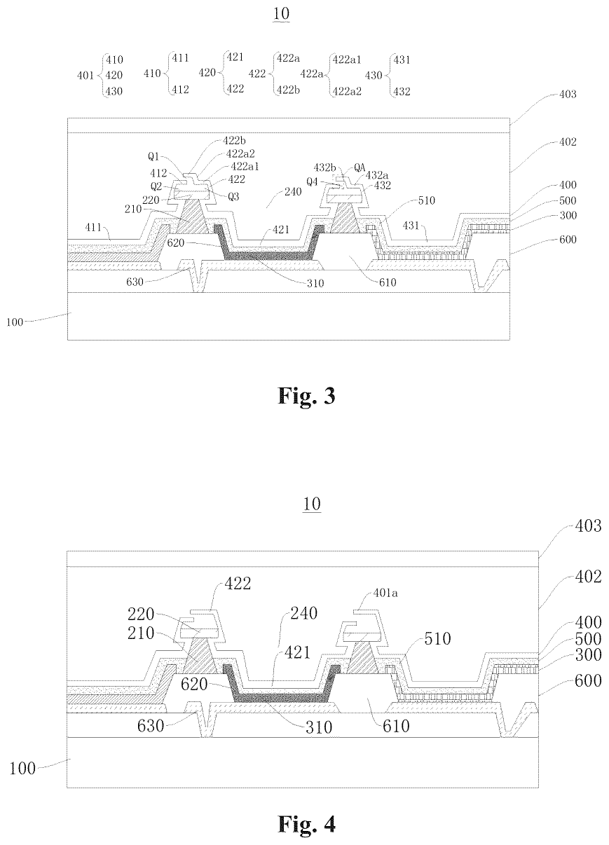

Referring to FIGS. 1 to 4, in which FIG. 1 shows a schematic structural diagram of a display panel 10 according to an embodiment of the present application, FIG. 2 shows a partially enlarged schematic structural diagram at M1 in FIG. 1, FIG. 3 shows a cross-sectional view at A-A in FIG. 2 in an example, and FIG. 4 shows a cross-sectional view at A-A in FIG. 2 in another example.

As shown in FIGS. 1 to 4, the embodiments of the first aspect of the present application provide a display panel 10 including: a base plate 100; an isolation structure 200 located at one side of the base plate 100; a plurality of isolation openings 240 encircled by the isolation structure 200; a light-emitting layer 300 located at one side of the base plate 100 and including a plurality of light-emitting units 310 arranged at intervals, the plurality of light-emitting units 310 being at least partially located in plurality of the isolation openings 240, respectively; and a first encapsulation layer 400 including a plurality of encapsulation portions 401 for encapsulating the plurality of light-emitting units 310, in which an orthographic projection of an encapsulation portion 401 corresponding to at least one of the plurality of light-emitting units 310 on the base plate 100 at least partially overlaps an orthographic projection of an encapsulation portion 401 corresponding to at least one of the light-emitting units 310 adjacent to the at least one light-emitting unit 310 on the base plate 100.

FIG. 2 and the subsequent related accompanying drawings illustrate the location of the encapsulation portions 401 by dashed lines, which do not limit the structures in the present application and are used to define the location and distribution range of the encapsulation portions 401.

The display panel 10 according to the embodiments of the present application includes the base plate 100, the isolation structure 200, the isolation openings 240, the light-emitting layer 300, and the first encapsulation layer 400. The isolation structure 200 is arranged on the base plate 100 and encircles the plurality of isolation openings 240, so as to separate the light-emitting layer 300 to form the light-emitting units 310 that are disconnected from each other, thereby reducing the crosstalk of carriers in the light-emitting layer 300 and improving the display effect of the display panel 10, and the light-emitting units 310 are prepared without a fine mask plate, which can reduce the development and use of the fine mask plate and reduce the preparation cost. The first encapsulation layer 400 includes the encapsulation portions 401 for encapsulating the light-emitting units 310, and the encapsulation portions 401 can provide encapsulation protection for the light-emitting units 310, and thus the effect of water and oxygen intrusion on the yield of the light-emitting units 310 is reduced. The orthographic projection of the encapsulation portion 401 corresponding to at least one of the light-emitting units 310 on the base plate 100 at least partially overlaps the orthographic projection of the encapsulation portion 401 corresponding to at least one of the light-emitting units 310 adjacent to the at least one light-emitting unit 310 on the base plate 100, so that the distribution area of the encapsulation portion 401 is great, and a portion of the adjacent encapsulation portions 401 overlap, which can increase the distribution area of the encapsulation portion 401 and improve the encapsulation effect. Moreover, at least one of the encapsulation portions 401 is covered by other encapsulation portions 401, the relative position between the covered encapsulation portion 401 and the isolation structure 200 is more stable, and the covered encapsulation portion 401 is less likely to be damaged, which can avoid encapsulation failure and further improve the yield and the using performance of the display panel 10.

Optionally, the plurality of isolation openings 240 are spaced apart along a row direction and a column direction, and a direction from the isolation opening 240 to an adjacent isolation opening 240 is the row direction or the column direction. The row direction may be a first direction X, and the column direction may be a second direction Y.

As shown in FIGS. 3 and 4, the display panel 10 further includes a second electrode layer 500 including a plurality of second electrodes 510 located in the isolation openings 240, and the second electrode 510 is located between a light-emitting structure and the encapsulation portion 401 and electrically connected with the isolation structure 200.

In these optional embodiments, the isolation structure 200 separates the second electrode layer 500 to form second electrodes 510 that are spaced apart from each other, and the second electrodes 510 that are spaced apart from each other are electrically connected through the isolation structure 200 to form a whole surface electrode, so as to ensure normal light emission of the light-emitting units 310.

In some optional embodiments, the light-emitting unit 310 includes a light-emitting structure, and an orthographic projection of the light-emitting structure on the base plate 100 is located within an orthographic projection of the second electrode 510 on the base plate 100.

In these optional embodiments, the orthographic projection of the light-emitting structure on the base plate 100 is located within the orthographic projection of the second electrode 510 on the base plate 100, i.e., the second electrode 510 is arranged covering the light-emitting structure to be used as an electrode of the light-emitting structure, so as to ensure normal light emission of the light-emitting units 310 and improve the display effect of the display panel 10.

Optionally, the light-emitting structure is spaced apart from the isolation structure 200, i.e., the various light-emitting structures are spaced apart from each other, so as to reduce the crosstalk of carriers between the light-emitting structures and reduce color-cross of the light-emitting units 310.

In some optional embodiments, the display panel 10 further includes a pixel defining layer 600 located on the base plate 100, the pixel defining layer 600 includes a pixel defining portion 610 and a plurality of pixel openings 620 encircled by the pixel defining portion 610, and the pixel opening 620 is communicated to the isolation opening 240.

In these optional embodiments, the pixel defining portion 610 of the pixel defining layer 600 encircles the plurality of pixel openings 620 to arrange the plurality of light-emitting units 310, so as to achieve normal light emission of the light-emitting units 310. Moreover, the pixel defining portion 610 defines the arrangement area of the light-emitting units 310 to reduce color-cross between the light-emitting units 310.

Optionally, the display panel 10 further includes a plurality of first electrodes 630 exposed by the pixel openings 620. One of the first electrode 630 and the second electrode 510 is used as the anode of the light-emitting unit 310, and the other one is used as the cathode of the light-emitting unit 310. In the embodiments of the present application, for example, the first electrode 630 is used as the anode of the light-emitting unit 310, and the second electrode 510 is used as the cathode of the light-emitting unit 310. Reference is made to patent applications No. 202310707209.0 and 202311346196.5 for the cathode.

Optionally, the light-emitting layer 300 includes an electron injection layer (EIL), an electron transport layer (ETL), a light-emitting material layer, a hole injection layer (HIL), and a hole transport layer (HTL).

Optionally, as shown in FIG. 3, the display panel 10 further includes a second encapsulation layer 402 located at a side of the first encapsulation layer 400 away from the base plate 100, and a third encapsulation layer 403 located at a side of the second encapsulation layer 402 away from the base plate 100. Optionally, the light-emitting units 310 include a plurality of first light-emitting units 311, a plurality of second light-emitting units 312, and a plurality of third light-emitting units 313, and the colors of lights emitted by the first light-emitting unit 311, the second light-emitting unit 312, and the third light-emitting unit 313 may be different from each other.

The base plate 100 may be arranged in various ways. For example, the base plate 100 may include a substrate and an array base plate 100 arranged on the substrate. Alternatively, the base plate 100 is the substrate. Alternatively, the base plate 100 includes a buffer layer and a support plate at a side away from the substrate.

The encapsulation portion 401 corresponding to the light-emitting unit 310 is an encapsulation portion 401 for encapsulating this light-emitting unit 310, and the orthographic projection of the light-emitting unit 310 on the base plate 100 is located within the orthographic projection of the encapsulation portion 401 corresponding to the light-emitting unit 310 on the base plate 100.

In some optional embodiments, as shown in FIGS. 2, 6, 8, and 9, orthographic projections of a plurality of adjacent encapsulation portions 401 on the base plate 100 encircle a plurality of hollow areas QB located within an orthographic projection of the isolation structure 200 on the base plate 100. Therefore, a portion of the isolation structure 200 can be exposed by the hollow area QB, and the second encapsulation layer 402 subsequently prepared may fill a second spacing corresponding to the hollow area QB and be connected in contact with the isolation structure 200.

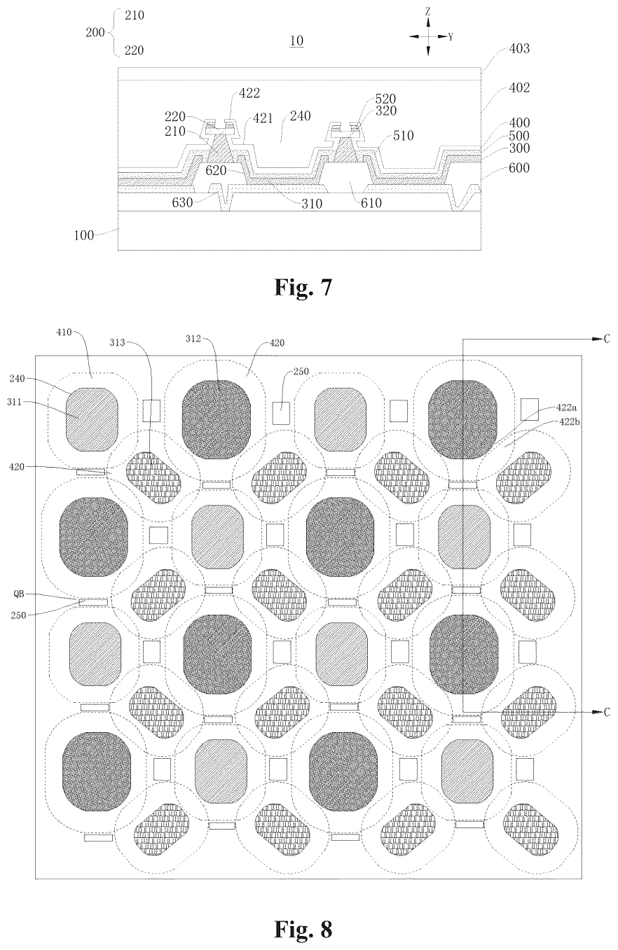

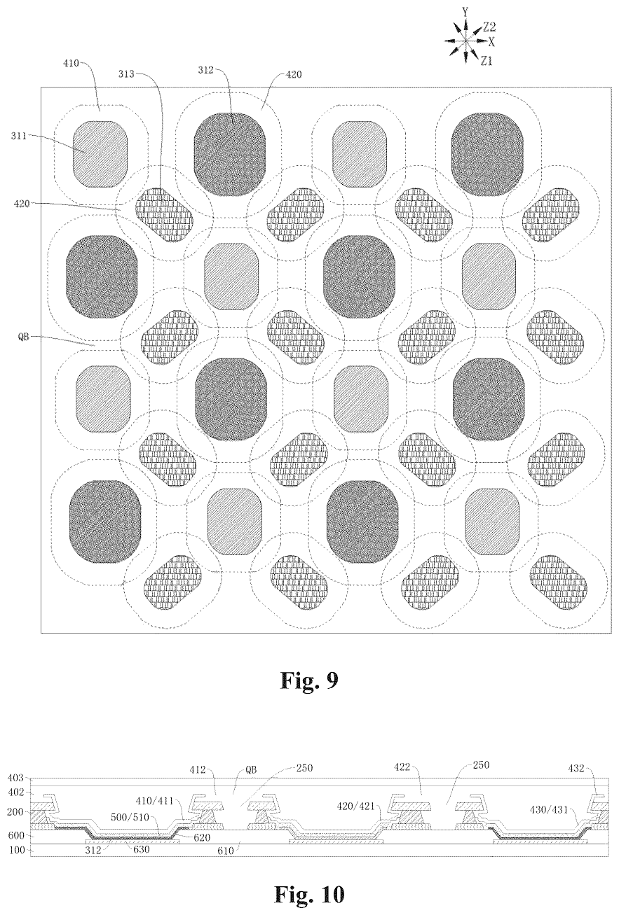

As shown in FIG. 7, the hollow area QB may be formed between the encapsulation portions 401 corresponding to the light-emitting units 310 of a same color. Alternatively, as shown in FIGS. 8 and 9, the hollow area QB may be formed between the encapsulation portions 401 corresponding to the light-emitting units 310 of different colors.

Optionally, as shown in FIG. 8, an orthographic projection of an encapsulation portion 401 corresponding to one of the light-emitting units 310 on the base plate 100 overlaps orthographic projections of the encapsulation portions 401 corresponding to a portion of the light-emitting units 310 adjacent to the light-emitting unit 310 on the base plate 100. Therefore, a same encapsulation portion 401 may be covered by a portion of the adjacent encapsulation portions 401.

Optionally, as shown in FIG. 2, one of the light-emitting units 310 is adjacent to N light-emitting units 310 at a periphery of the light-emitting unit 310, an orthographic projection of an encapsulation portion 401 corresponding to the light-emitting unit 310 on the base plate overlaps orthographic projections of the encapsulation portions 401 corresponding to M light-emitting units 310 adjacent to the light-emitting unit 310 at the periphery of the light-emitting unit 310 on the base plate 100, and M<N.

Optionally, as shown in FIGS. 8 and 10, the isolation structure 200 is further provided with a plurality of light-transmitting openings 250, and an orthographic projection of the light-transmitting opening 250 on the base plate 100 at least partially overlaps an orthographic projection of the hollow area QB on the base plate 100.

In these optional embodiments, the isolation structure 200 is provided with the light-transmitting openings 250, which can increase the light transmittance of the display panel 10 and achieve light transmitting and display. The light-transmitting opening 250 and the hollow area QB at least partially overlap, which can reduce the distribution area of the encapsulation portion 401 in the area where the light-transmitting opening 250 is located and ensure the light transmitting effect.

Optionally, as shown in FIGS. 1 and 8, the display panel 10 further includes a main display area AA1 and a functional display area AA2, and the light-transmitting opening 250 is located in the functional display area AA2. Therefore, the light transmittance of the functional display area AA2 is increased, so that the functional display area AA2 can achieve display and the corresponding functions. The functional display area AA2 may be an under-screen fingerprint identification area, a photosensitive module arrangement area, and the like.

Optionally, as shown in FIG. 8, the plurality of light-transmitting openings 250 are arranged at intervals at the periphery of a same isolation opening 240, so as to further increase the light transmittance of the display panel 10.

In some optional embodiments, as shown in FIGS. 8 to 10, a plurality of light-emitting units 310 are distributed at intervals along the first direction X to form a pixel row, and the orthographic projections of the encapsulation portions 401 corresponding to the adjacent light-emitting units 310 in a same pixel row on the base plate 100 are spaced apart.

In these optional embodiments, the encapsulation portions 401 corresponding to the adjacent light-emitting units 310 in a same pixel row are spaced apart, i.e., the encapsulation portions 401 corresponding to the adjacent light-emitting units 310 in a same pixel row do not overlap, which facilitates arranging a light-transmitting hole between the adjacent light-emitting units 310 in a same pixel row.

Optionally, as shown in FIGS. 8 and 9, a plurality of light-emitting units 310 are distributed at intervals along the second direction Y to form a pixel column, the orthographic projections of the encapsulation portions 401 corresponding to the adjacent light-emitting units 310 in a same pixel column on the base plate 100 are spaced apart, and the first direction X and the second direction Y are perpendicular. The encapsulation portions 401 corresponding to the adjacent light-emitting units 310 in a same pixel column do not overlap, which facilitates arranging a light-transmitting hole between the adjacent light-emitting units 310 in a same pixel column.

Optionally, if a plurality of light-emitting units 310 are distributed in rows and columns along the first direction X and the second direction Y, the spacing between two adjacent light-emitting units 310 in a same pixel row or a same pixel column is great, and the encapsulation portions 401 corresponding to two adjacent light-emitting units 310 in a same pixel row or a same pixel column do not overlap, which can simplify the preparation of the encapsulation portions 401 and reduce the preparation difficulty due to the encapsulation portions 401 being too large, and also facilitate arranging the light-transmitting openings 250 in a larger space to increase the light transmittance of the display panel 10.

Optionally, as shown in FIGS. 8 and 9, a plurality of light-emitting units 310 are distributed at intervals along a third direction to form a pixel repeat unit, the orthographic projections of the encapsulation portions 401 corresponding to the adjacent light-emitting units 310 in a same pixel repeat unit on the base plate 100 at least partially overlap, and the angle between the third direction and the first direction X is in the range of 40° to 50°. Optionally, the third direction may be the direction Z1 or Z2 in FIG. 9.

In these optional embodiments, within a same pixel repeat unit, the adjacent light-emitting units 310 are distributed along the third direction, and the angle between the third direction and the first direction X is in the range of 40° to 50°, and thus the light-emitting units 310 in two adjacent rows are staggered. For two adjacent pixel rows, the light-emitting unit 310 in one pixel row is located correspondingly between two adjacent light-emitting units 310 within the other pixel row, and a portion of the light-emitting unit 310 in one pixel row may extend between two adjacent light-emitting units 310 within the other pixel row, so that the spacing between two adjacent light-emitting units 310 within a same pixel repeat unit is small. The orthographic projections of the encapsulation portions 401 corresponding to the adjacent light-emitting units 310 in a same pixel repeat unit on the base plate 100 at least partially overlap, i.e., the encapsulation portions 401 corresponding to two adjacent light-emitting units 310 with small spacing overlap, and the encapsulation portions 401 overlap in an area with small spacing, which can increase the distribution area of the encapsulation portion 401 and reduce the encapsulation failure of the encapsulation portion 401 that is covered.

Optionally, as shown in FIGS. 8 and 9, the light-emitting units 310 include a plurality of first light-emitting units 311, a plurality of second light-emitting units 312, and a plurality of third light-emitting units 313, and the pixel rows include a first pixel row formed by the first light-emitting unit 311 and the second light-emitting unit 312 being distributed alternately along the first direction X, and a second pixel row formed by a plurality of third light-emitting units 313 being distributed at intervals along the first direction X, in which the first pixel row and the second pixel row are distributed alternately along the second direction Y, and the light-emitting unit 310 in the first pixel row and the light-emitting unit 310 in the second pixel row are staggered, so that the third light-emitting unit 313 is located correspondingly between the first light-emitting unit 311 and the second light-emitting unit 312 that are adjacent.

In these optional embodiments, the pixel rows include the first pixel row formed by the first light-emitting unit 311 and the second light-emitting unit 312 and the second pixel row formed by a plurality of third light-emitting units 313, and the first pixel row and the second pixel rows are distributed alternately, so that a plurality of first light-emitting units 311, a plurality of second light-emitting units 312, and a plurality of third light-emitting units 313 are uniformly distributed in the display area of the display panel 10. The light-emitting unit 310 in the first pixel row and the light-emitting unit 310 in the second pixel row are staggered, so that the third light-emitting unit 313 is located correspondingly between the first light-emitting unit 311 and the second light-emitting unit 312 that are adjacent, which can reduce the spacing between the third light-emitting unit 313 and the first light-emitting unit 311, the second light-emitting unit 312 and increase the pixel density, thereby improving the light emitting and display effect.

The spacing between the first light-emitting unit 311 and the second light-emitting unit 312 that are adjacent within the first pixel row is great, the spacing between the adjacent third light-emitting units 313 within the second pixel row is great, while the spacing between the third light-emitting unit 313 and the first light-emitting unit 311 or the second light-emitting unit 312 that are adjacent along the third direction is small.

Optionally, as shown in FIGS. 8 and 9, in the first pixel row, the orthographic projection of the encapsulation portion 401 corresponding to the first light-emitting unit 311 on the base plate 100 and the orthographic projection of the encapsulation portion 401 corresponding to the second light-emitting unit 312 on the base plate 100 are spaced apart. Optionally, in the second pixel row, the orthographic projections of the encapsulation portions 401 corresponding to the adjacent third light-emitting units 313 on the base plate 100 are spaced apart. Optionally, the orthographic projection of the encapsulation portion 401 corresponding to the first light-emitting unit 311 on the base plate 100 and the orthographic projection of the encapsulation portion 401 corresponding to the third light-emitting unit 313 on the base plate 100 at least partially overlap. Optionally, the orthographic projection of the encapsulation portion 401 corresponding to the second light-emitting unit 312 on the base plate 100 and the orthographic projection of the encapsulation portion 401 corresponding to the third light-emitting unit 313 on the base plate 100 at least partially overlap. That is, the orthographic projections of the encapsulation portions 401 corresponding to the first light-emitting unit 311 and the third light-emitting unit 313 that are adjacent in a same first pixel repeat unit on the base plate 100 overlap, and the orthographic projections of the encapsulation portions 401 corresponding to the third light-emitting unit 313 and the second light-emitting unit 312 that are adjacent in a same second pixel repeat unit on the base plate 100 overlap.

Optionally, as shown in FIGS. 8 and 9, the pixel column include a first pixel column formed by the first light-emitting unit 311 and the second light-emitting unit 312 being distributed alternately along the second direction Y, and a second pixel column formed by a plurality of third light-emitting units 313 being distributed at intervals along the second direction Y, in which the first pixel column and the second pixel column are distributed alternately along the first direction X, and the light-emitting unit in the first pixel column and the light-emitting unit in the second pixel column are staggered, so that the third light-emitting unit 313 is located correspondingly between the first light-emitting unit 311 and the second light-emitting unit 312 that are adjacent, which can reduce the spacing between the third light-emitting unit 313 and the first light-emitting unit 311, the second light-emitting unit 312 and increase the pixel density, thereby improving the light emitting and display effect.

If the first light-emitting unit 311, the second light-emitting unit 312, and the third light-emitting unit 313 are distributed in the above manner, the first light-emitting unit 311 and the third light-emitting unit 313 are arranged along the third direction to form a first pixel repeat unit, and the second light-emitting unit 312 and the third light-emitting unit 313 are arranged along the third direction to form a second pixel repeat unit. The orthographic projections of the encapsulation portions 401 corresponding to the first light-emitting unit 311 and the third light-emitting unit 313 that are adjacent in a same first pixel repeat unit on the base plate 100 at least partially overlap, and the orthographic projections of the encapsulation portions 401 corresponding to the third light-emitting unit 313 and the second light-emitting unit 312 that are adjacent in a same second pixel repeat unit on the base plate 100 at least partially overlap.

In some optional embodiments, as shown in FIG. 11, orthographic projections of the encapsulation portions 401 corresponding to a plurality of adjacent light-emitting units 310 on the base plate 100 completely cover an orthographic projection of the isolation structure 200 between the plurality of adjacent light-emitting units 310 on the base plate 100. That is, the edges of the periphery of a same encapsulation portion 401 all overlap the covering segments 401a of other encapsulation portions 401, which further reduce the encapsulation failure of some encapsulation portions 401. As shown in FIGS. 8 and 9, the orthographic projections of the encapsulation portions 401 corresponding to any adjacent two of the light-emitting units 310 on the base plate 100 at least partially overlap, so as to further reduce the encapsulation failure of some encapsulation portions 401.

In some optional embodiments, as shown in FIGS. 2, 3, and 12, the light-emitting units 310 include a plurality of first light-emitting units 311 and a plurality of second light-emitting units 312 arranged adjacently. The first light-emitting unit 311 and the second light-emitting unit 312 may be configured to emit lights of the same or different colors. In the embodiments of the present application, for example, the first light-emitting unit 311 and the second light-emitting unit 312 are configured to emit lights of different colors.

Optionally, the encapsulation portion 401 is located at a side of the light-emitting unit 310 away from the base plate 100, and the encapsulation portion 401 covers a sidewall of the isolation structure 200 towards the isolation opening 240 and extends to a side of the isolation structure 200 away from the base plate 100, i.e., the encapsulation portion 401 not only covers the isolation opening 240, but also covers a portion of the isolation structure 200 surrounding the isolation opening 240, which can increase the distribution area of the encapsulation portion 401 and improve the encapsulation effect of the encapsulation portion 401.

Optionally, as shown in FIGS. 1, 12, and 13, the plurality of encapsulation portions 401 includes a plurality of first encapsulation portions 410 for encapsulating the plurality of first light-emitting units 311 and a plurality of second encapsulation portions 420 for encapsulating the plurality of second light-emitting units 312, and at least a portion of the plurality of second encapsulation portions 420 further extends to a side of the first encapsulation portion 410 away from the base plate 100. On the one hand, the distribution area of the second encapsulation portion 420 can be increased to improve the encapsulation effect of the second encapsulation portion 420; on the other hand, a portion of the first encapsulation portion 410 is covered by the second encapsulation portion 420, which can improve the stability of the relative position between the first encapsulation portion 410 and the isolation structure 200, and reduce the failure of the first encapsulation portion 410.

Optionally, as shown in FIGS. 1, 12, and 13, the light-emitting units 310 further include a plurality of third light-emitting units 313 arranged adjacent to at least one of the plurality of first light-emitting units 311 or the plurality of second light-emitting units 312, and the plurality of encapsulation portions 401 include a plurality of third encapsulation portions 430 for encapsulating the plurality of third light-emitting units 313. The third encapsulation portion 430 is configured to provide encapsulation protection for the third light-emitting unit 313. The color of light emitted by the third light-emitting unit 313 may be the same as or different from those of the first light-emitting unit 311 and the second light-emitting unit 312. In the embodiments of the present application, for example, the colors of lights emitted by the first light-emitting unit 311, the second light-emitting unit 312, and the third light-emitting unit 313 are different from each other.

Optionally, the third encapsulation portion 430 extends to a side of at least one first encapsulation portion 410 away from the base plate 100. On the one hand, the distribution area of the third encapsulation portion 430 can be increased to improve the encapsulation effect of the third encapsulation portion 430; on the other hand, a portion of the first encapsulation portion 410 is covered by the third encapsulation portion 430, which can improve the stability of the relative position between the first encapsulation portion 410 and the isolation structure 200, and reduce the encapsulation failure of the first encapsulation portion 410.

Optionally, the third encapsulation portion 430 extends to a side of at least one second encapsulation portion 420 away from the base plate 100. On the one hand, the distribution area of the third encapsulation portion 430 can be increased to improve the encapsulation effect of the third encapsulation portion 430; on the other hand, a portion of the second encapsulation portion 420 is covered by the third encapsulation portion 430, which can improve the stability of the relative position between the second encapsulation portion 420 and the isolation structure 200, and reduce the encapsulation failure of the second encapsulation portion 420.

Optionally, the third encapsulation portion 430 extends to a side of at least one first encapsulation portion 410 away from the base plate 100, and the third encapsulation portion 430 extends to a side of at least one second encapsulation portion 420 away from the base plate 100. On the one hand, the distribution area of the third encapsulation portion 430 can be further increased to improve the encapsulation effect of the third encapsulation portion 430; on the other hand, a portion of the first encapsulation portion 410 and a portion of the second encapsulation portion 420 are covered by the third encapsulation portion 430, which can improve the stability of the relative position between the second encapsulation portion 420 and the isolation structure 200, and reduce the encapsulation failure of the second encapsulation portion 420.

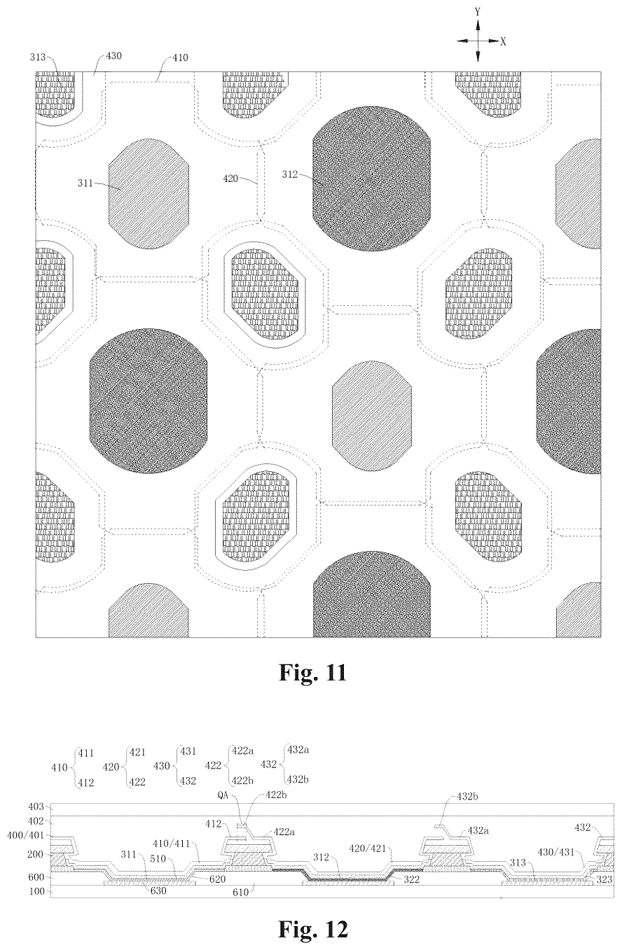

In some optional embodiments, as shown in FIGS. 12 to 14, the first encapsulation portion 410 includes a first segment 411 and a second segment 412 connected to each other, the first segment 411 is located at a side of the light-emitting unit 310 away from the base plate 100 and covers the sidewall of the isolation structure 200 towards the isolation opening 240, and the second segment 412 is located at the side of the isolation structure 200 away from the base plate 100; and the second encapsulation portion 420 includes a third segment 421 and a fourth segment 422 connected to each other, the third segment 421 is located at a side of the light-emitting unit 310 away from the base plate 100 and covers the sidewall of the isolation structure 200 towards the isolation opening 240, and the fourth segment 422 is located at the side of the isolation structure 200 away from the base plate 100; in which at least a portion of the fourth segment 422 extends to a side of the second segment 412 away from the base plate 100.

In these optional embodiments, the first encapsulation portion 410 includes the first segment 411 and the second segment 412, and the second segment 412 covers a portion of the isolation structure 200 to increase the distribution area of the first encapsulation portion 410. The second encapsulation portion 420 includes the third segment 421 and the fourth segment 422, and the fourth segment 422 covers the isolation structure 200 to increase the distribution area of the second encapsulation portion 420. The second segment 412 and the fourth segment 422 are both located above the isolation structure 200, and the second segment 412 and the fourth segment 422 may at least partially overlap above the isolation structure 200, so that the fourth segment 422 may cover a portion of the second segment 412 to reduce the damage to the second segment, which otherwise causes encapsulation failure.

Optionally, as shown in FIGS. 12 to 14, the orthographic projections of the second segment 412 and the fourth segment 422 on the base plate 100 at least partially overlap and form an overlapping area QA, and the overlapping area QA is located within the orthographic projection of the isolation structure 200 on the base plate 100, i.e., the overlapping area QA is located above the isolation structure 200.

Optionally, the orthographic projections of the second segment 412 and a sixth segment 432 on the base plate 100 at least partially overlap and form an overlapping area QA. Optionally, the orthographic projections of the sixth segment 432 and the fourth segment 422 on the base plate 100 at least partially overlap and form an overlapping area QA. That is, as shown in FIG. 2, the overlapping area QA may be formed by the orthographic projections of any two of the second segment 412, the fourth segment 422, and the sixth segment 432 on the base plate 100 at least partially overlapping.

Optionally, the area of the orthographic projection of the overlapping area QA on the base plate 100 is in the range of 15% to 75% of the area of the orthographic projection of a top surface 201 of the isolation structure 200 away from the base plate 100 on the base plate 100. For example, the area of the orthographic projection of the overlapping area QA on the base plate 100 is 15%, 16%, 25%, 39%, 55%, 75%, etc., of the area of the orthographic projection of the top surface 201 of the isolation structure 200 away from the base plate 100 on the base plate 100, so as to avoid the area of the overlapping area QA being too less, which otherwise affects the encapsulation performance the encapsulation portion 401, and also avoid the area of the overlapping area QA and the distribution area of the encapsulation portion 401 being too great, which otherwise causes incomplete removal of the encapsulation material layer due and affects the preparation of the subsequent film layers.

Optionally, as shown in FIGS. 12 to 14, the fourth segment 422 includes a first sub-segment 422a and a second sub-segment 422b, the first sub-segment 422a is connected between the third segment 421 and the second sub-segment 422b, and the second sub-segment 422b is located at the side of the second segment 412 away from the base plate 100. The fourth segment 422 is arranged along a bent path, a portion of the fourth segment 422 (i.e., the second sub-segment 422b) is located above the second segment 412, and the other portion of the fourth segment 422 (i.e., the first sub-segment 422a) may be arranged side by side with the second segment 412.

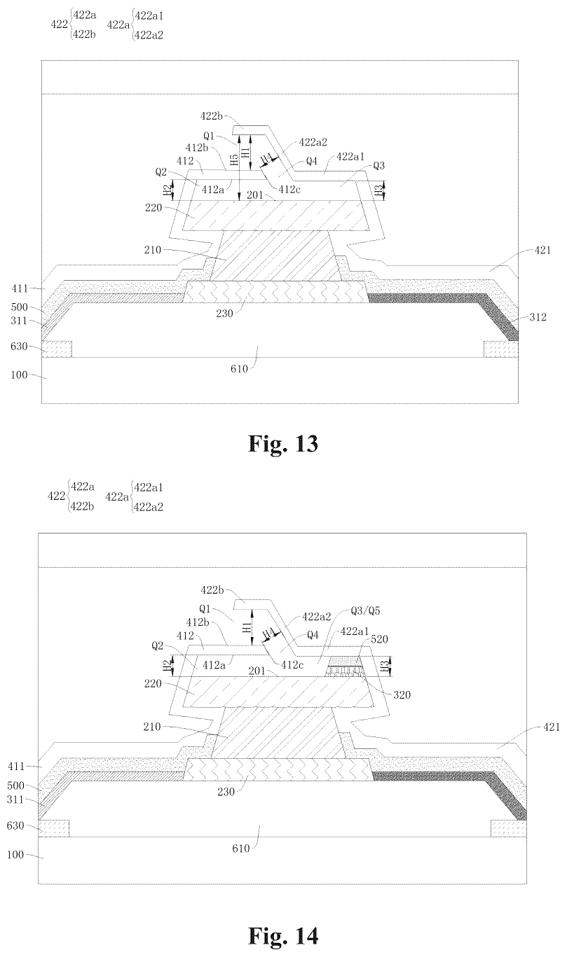

Optionally, as shown in FIGS. 8 and 13, the second sub-segment 422b is connected to a periphery of the first sub-segment 422a away from the third segment 421, and the second sub-segment 422b is arranged around a portion of the first sub-segment 422a, i.e., the second sub-segment 422b is connected to an edge of the first sub-segment 422a away from the third segment 421.

Optionally, as shown in FIGS. 13 and 14, the second segment 412 includes a first surface 412a and a second surface 412b arranged opposite to each other in a thickness direction Z of the display panel 10, the first surface 412a is arranged towards the base plate 100, the second surface 412b is arranged away from the base plate 100, and the second segment 412 further includes a first side surface 412c connecting the first surface 412a and the second surface 412b; and an orthographic projection of the second sub-segment 422b on the base plate 100 is located within an orthographic projection of the second surface 412b on the base plate 100. That is, the second sub-segment 422b is located above the first surface 412a, an end of the second sub-segment 422b away from the first sub-segment 422a do not extend beyond the second segment 412, and the second sub-segment 422b do not extend to the first segment 411, so as to avoid the area of the fourth segment 422 being too great, which otherwise affects the preparation of the subsequent film layers.

Optionally, as shown in FIGS. 13 and 14, an orthographic projection of the first sub-segment 422a on the base plate 100 and an orthographic projection of the second surface 412b on the base plate 100 are spaced apart, so that the first sub-segment 422a may be arranged side by side with the second segment 412.

Optionally, as shown in FIGS. 13 and 14, since the fourth segment 422 covers the second segment 412, and a portion of the fourth segment 422 is located at the side of the second segment 412 away from the base plate 100, in manufacturing the display panel 10, a first light-emitting material layer and a first encapsulation material layer may be first arranged on the isolation structure 200, and then patterned to remove the first light-emitting material layer and the first encapsulation material layer in the area where a second isolation opening 240 and a third isolation opening 240 are located, so as to form the first light-emitting unit 311 located in a first isolation opening 240 and the corresponding first encapsulation portion 410. After the first light-emitting unit 311 and the first encapsulation portion 410 are prepared, a second light-emitting material layer and a second encapsulation material layer are arranged on the isolation structure 200 and patterned to remove the second light-emitting material layer and the second encapsulation material layer in the area where the first encapsulation portion 410 and the third isolation opening 240 are located, so as to form the second light-emitting unit 312 located in the second isolation opening 240 and the corresponding second encapsulation portion 420. The fourth segment 422 covers the second segment 412, a portion of the fourth segment 422 is located at the side of the second segment 412 away from the base plate 100, and the second encapsulation portion protects the first encapsulation portion to avoid damage to the first encapsulation portion.

Optionally, as shown in FIG. 13, a distance H3 between the first sub-segment 422a and the isolation structure 200 along the thickness direction Z of the display panel 10 is less than a distance H5 between the second sub-segment 422b and the isolation structure 200 along the thickness direction Z of the display panel 10. That is, the distance between the second sub-segment 422b and the isolation structure 200 is greater, so that a portion of the second segment 412 may be arranged between the first sub-segment 422a and the isolation structure 200.

Optionally, as shown in FIG. 13, the second sub-segment 422b and the second segment 412 are spaced apart along the thickness direction Z of the display panel 10 and form a first gap Q1. In preparing the second encapsulation portion 420, a portion of the second light-emitting material layer is arranged under the second encapsulation material layer and subsequently etched to form the first gap Q1.

Optionally, as shown in FIG. 13, the second segment 412 and the isolation structure 200 are spaced apart along the thickness direction Z of the display panel 10 and form a second gap Q2. In preparing the first encapsulation portion 410, a portion of the first light-emitting material layer is arranged under the first encapsulation material layer and subsequently etched to form the second gap Q2.

Optionally, as shown in FIG. 13, the first sub-segment 422a and the isolation structure 200 are spaced apart along the thickness direction Z of the display panel 10 and form a third gap Q3. That is, the third gap Q3 is formed when the second light-emitting material layer between the first sub-segment 422a and the isolation structure 200 is removed.

As shown in FIG. 13, at least one of the encapsulation portions 401 forms gaps with the encapsulation portion 401 adjacent to the at least one encapsulation portion 401 and the isolation structure 200; and the second encapsulation layer 402 fills at least a portion of the gaps. The gaps may include at least one of the first gap Q1, the second gap Q2, or the third gap Q3, i.e., the second encapsulation layer 402 fills at least one of the first gap Q1, the second gap Q2, or the third gap Q3.

Optionally, the second encapsulation layer 402 as described above is at least partially filled into the first gap Q1; or the second encapsulation layer 402 is at least partially filled into the second gap Q2; or the second encapsulation layer 402 is at least partially filled into the third gap Q3, so that the second encapsulation layer 402 can provide support to the first sub-segment 422a, the second sub-segment 422b, or the second segment 412.

Optionally, as shown in FIG. 12, the light-emitting unit 310 includes a first electrode 630, a light-emitting structure, and a second electrode 510 stacked in a direction away from the base plate 100, and the first electrode 630 and the second electrode 510 are configured to drive the light-emitting structure to emit light.

Optionally, a size H2 of the second gap Q2 along the thickness direction Z of the display panel 10 is greater than or equal to a sum of thicknesses of the second electrode 510 and the light-emitting structure in the first light-emitting unit 311.

In these optional embodiments, in preparing the first light-emitting unit 311, the first encapsulation material layer for preparing the first encapsulation portion 410 covers a first conductive material layer for preparing the second electrode 510 of the first light-emitting unit 311 and the first light-emitting material layer for preparing the light-emitting structure of the first light-emitting unit 311, and the first light-emitting material layer and the first conductive material layer falling on the isolation structure 200 are removed to form the second gap Q2, therefore the size H2 of the second gap Q2 along the thickness direction Z of the display panel 10 is equal to the sum of thicknesses of the second electrode 510 and the light-emitting structure in the first light-emitting unit 311. When a functional layer such as a light extraction layer is arranged on the first light-emitting material layer, a light extraction material layer on the isolation structure 200 is also removed to form the second gap Q2, therefore the size H2 of the second gap Q2 along the thickness direction Z of the display panel 10 may be greater than the sum of thicknesses of the second electrode 510 and the light-emitting structure in the first light-emitting unit 311.

Optionally, a size H3 of the third gap Q3 along the thickness direction Z of the display panel 10 is greater than or equal to a sum of thicknesses of the second electrode 510 and the light-emitting structure in the second light-emitting unit 312.

In these optional embodiments, in preparing the second light-emitting unit 312, the second encapsulation material layer for preparing the second encapsulation portion 420 covers a second conductive material layer for preparing the second electrode 510 of the second light-emitting unit 312 and the second light-emitting material layer for preparing the light-emitting structure of the second light-emitting unit 312, and the second light-emitting material layer and the second conductive material layer falling on the isolation structure 200 are removed to form the third gap Q3, therefore the size H3 of the third gap Q3 along the thickness direction Z of the display panel 10 is equal to the sum of thicknesses of the second electrode 510 and the light-emitting structure in the second light-emitting unit 312. When a functional layer such as a light extraction layer is arranged on the second light-emitting material layer, a light extraction material layer on the isolation structure 200 is also removed to form the third gap Q3, therefore the size H3 of the third gap Q3 along the thickness direction Z of the display panel 10 may be greater than the sum of thicknesses of the second electrode 510 and the light-emitting structure in the second light-emitting unit 312.

Optionally, a size H1 of the first gap Q1 along the thickness direction Z of the display panel 10 is greater than or equal to the sum of thicknesses of the second electrode 510 and the light-emitting structure in the second light-emitting unit 312.

In these optional embodiments, in preparing the second light-emitting unit 312, the second encapsulation material layer for preparing the second encapsulation portion 420 covers a second conductive material layer for preparing the second electrode 510 of the second light-emitting unit 312 and the second light-emitting material layer for preparing the light-emitting structure of the second light-emitting unit 312, and the second light-emitting material layer and the second conductive material layer falling on the second segment 412 are removed to form the first gap Q1, therefore the size H1 of the first gap Q1 along the thickness direction Z of the display panel 10 is equal to the sum of thicknesses of the second electrode 510 and the light-emitting structure in the second light-emitting unit 312. When a functional layer such as a light extraction layer is arranged on the second light-emitting material layer, a light extraction material layer on the second segment 412 is also removed to form the first gap Q1, therefore the size H1 of the first gap Q1 along the thickness direction Z of the display panel 10 may be greater than the sum of thicknesses of the second electrode 510 and the light-emitting structure in the second light-emitting unit 312.

Optionally, the size H2 of the second gap Q2 along the thickness direction Z of the display panel 10 is less than the size H1 of the first gap Q1 along the thickness direction Z of the display panel 10. The size of the first gap Q1 is great, so that the etching solution can better enter the third gap Q3 via the first gap Q1 to remove the second light-emitting material layer at the third gap Q3.

Additionally or alternatively, the size H2 of the second gap Q2 along the thickness direction Z of the display panel 10 is less than the size H3 of the third gap Q3 along the thickness direction Z of the display panel 10. The size of the third gap Q3 is great, so that the etching solution can better enter the third gap Q3 via the first gap Q1 to remove the second light-emitting material layer at the third gap Q3.

Additionally or alternatively, the size H1 of the first gap Q1 along the thickness direction Z of the display panel 10 is equal to the size H3 of the third gap Q3 along the thickness direction Z of the display panel 10. The third gap Q3 and the first gap Q1 are formed by removing a portion of the second light-emitting material layer at a side of the first sub-segment 422a and the second sub-segment 422b towards the base plate 100, and thus the third gap Q3 and the first gap Q1 may be the same.

Optionally, as shown in FIGS. 7 and 14, the light-emitting layer 300 further includes a redundant unit 320, and at least a portion of the redundant unit 310 is located in the third gap Q3. In these optional embodiments, in preparing the light-emitting unit 310, a portion of the light-emitting material may fall into the third gap Q3, and since the second segment 412 and the fourth segment 422 overlap and form the first gap Q1, it is difficult for the etching solution to flow into the third gap Q3, which in turn results in the residual light-emitting material to form the redundant unit 320. The redundant unit 320 may provide support to a portion of the fourth segment 422, so as to reduce the possibility of fracture at the connecting position between the fourth segment 422 and the third segment 421.

Optionally, as shown in FIG. 14, the redundant unit 320 encircles a hollow portion Q5, and an orthographic projection of the hollow portion Q5 on the base plate 100 is located within the orthographic projection of the isolation structure 200 on the base plate 100. In preparing the second encapsulation layer 402, the second encapsulation layer 402 may be deposited into the hollow portion Q5, thereby causing the second encapsulation layer 402 to contact the isolation structure 200 and improving the encapsulation effect on the isolation structure 200.

In some optional embodiments, as shown in FIGS. 7 and 14, a plurality of redundant electrodes 520 are provided between at least a portion of the plurality of fourth segments 422 and the isolation structure 200. In these optional embodiments, in preparing the second electrode 510, a portion of the electrode material may fall into the third gap Q3 and it is difficult for the etching solution to flow into the third gap Q3, which in turn results in the residual electrode material to form the redundant electrodes 520. The redundant electrodes 520 may provide support to a portion of the fourth segment 422, so as to reduce the possibility of fracture at the connecting position between the fourth segment 422 and the third segment 421.

Optionally, if the display panel 10 includes the third gap Q3 as described above, the redundant electrode 520 is located within the third gap Q3 as described above, so as to reduce the possibility of fracture at the connecting position between the fourth segment 422 and the third segment 421.

Optionally, if the light-emitting unit 310 includes the first electrode 630, the light-emitting structure, and the second electrode 510 stacked in the direction away from the base plate 100, the second electrode 510 and the redundant electrode 520 are of a same material. Therefore, the redundant electrode 520 and the second electrode 510 may be prepared in a same process step, which can simplify the preparation process of the display panel 10.

In some optional embodiments, as shown in FIG. 10, at least a portion of the plurality of second segments 412 and at least a portion of the plurality of fourth segments 422 are spaced apart. For example, a portion of the plurality of second segments 412 and a portion of the plurality of fourths segment 422 overlap, and a portion of the plurality of second segments 412 and a portion of the plurality of fourth segments 422 are spaced apart, the user can select the overlapping area QA and the spacing area according to the process and usage requirements.

Optionally, as described above, as shown in FIGS. 13 and 14, the fourth segment 422 includes a first sub-segment 422a and a second sub-segment 422b, the first sub-segment 422a includes a first body portion 422a1 and a connecting portion 422a2, the first body portion 422a1 is connected to the third segment 421, the connecting portion 422a2 is connected between the first body portion 422a1 and the second sub-segment 422b, and an orthographic projection of the first body portion 422a1 on the base plate 100 is spaced apart from an orthographic projection of the second segment 412 on the base plate 100.

In these optional embodiments, the first sub-segment 422a extends along a bent path to form the first body portion 422a1 and the connecting portion 422a2, the first body portion 422a1 is configured to be connected with the third segment 421 and is spaced apart from the second segment 412, which can reduce the mutual effect between the first encapsulation portion 410 and the second encapsulation portion 420.

Optionally, as shown in FIGS. 13 and 14, a first spacing Q4 is formed between the connecting portion 422a2 and the first side surface 412c. In etching the second encapsulation portion 420, the etching solution can enter the third gap Q3 via the first spacing Q4 to remove the redundant second light-emitting material layer.

Optionally, as shown in FIGS. 13 and 14, the second segment 412 has a first side surface 412c towards the first sub-segment 422a, and a size H4 of the first spacing Q4 along a normal direction of the first side surface 412c is less than the size H1 of the first gap Q1 along the thickness direction Z of the display panel 10, so that the size of the first spacing Q4 is less while the size of the first gap Q1 is greater, and the etching solution can be better enter the third gap Q3 via the first gap Q1 and the first spacing Q4.

Optionally, as shown in FIGS. 13 and 14, an angle between the first side surface 412c and the first surface 412a is less than 90 degrees, so that the first side surface 412c is tilted towards the first segment 411 in the direction away from the base plate 100, and thus the etching solution can flow along the first side surface 412c into the third gap Q3.

In some other optional embodiments, as shown in FIGS. 2, 15, and 16, at least a portion of the plurality of second segments 412 and at least a portion of the plurality of fourth segments 422 are interconnected. Therefore, the second segment 412 and the fourth segment 422 can support each other to further reduce the encapsulation failure of the encapsulation portion 401.

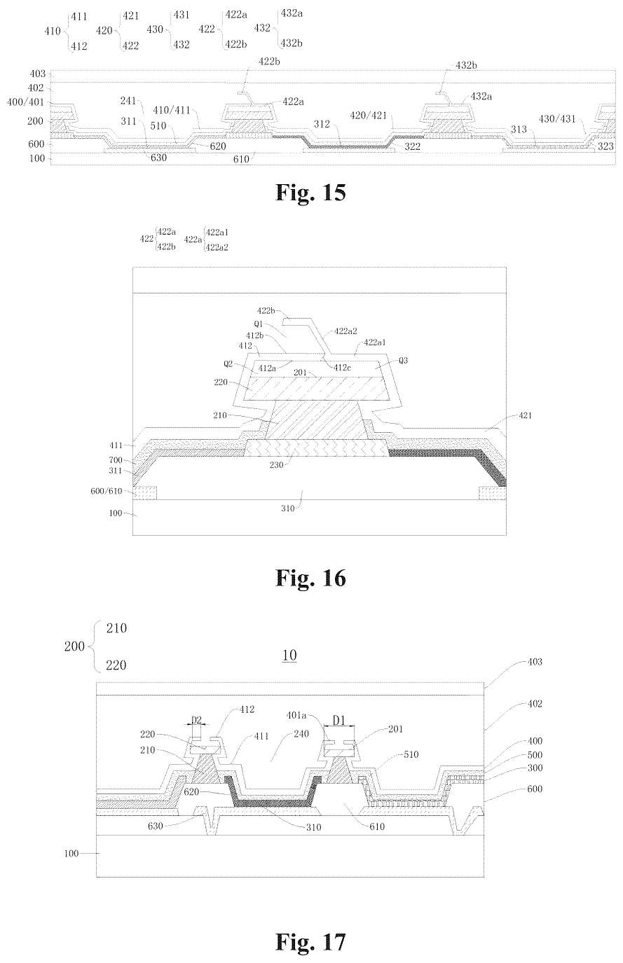

Optionally, as shown in FIGS. 15 and 16, the second segment 412 includes the first side surface 412c as described above, and the fourth segment 422 and the first side surface 412c are interconnected, so that the second segment 412 and a portion of the fourth segment 422 can support each other to further reduce the encapsulation failure of the encapsulation portion.

Optionally, as shown in FIGS. 15 and 16, the angle between the first side surface 412c and the first surface 412a is greater than or equal to 90 degrees, and along a direction away from the isolation structure 200, the first side surface 412c extends close to the fourth segment 422, which facilitates the interconnection of the first side surface 412c and the fourth segment 422.

Optionally, as shown in FIGS. 15 and 16, if the fourth segment 422 includes the first sub-segment 422a and the second sub-segment 422b as described above, and the first sub-segment 422a includes the first body portion and the connecting portion 422a2, the first side surface 412c may be connected to the connecting position between the first body portion and the connecting portion 422a2.

In some optional embodiments, as shown in FIGS. 3 and 13 to 16, the display panel 10 further includes a second encapsulation layer 402 located at a side of the first encapsulation layer 400 away from the base plate 100 and contacting the isolation structure 200, so as to increase the area of the isolation structure 200 covered by the encapsulation layer and improve the encapsulation effect of the encapsulation layer.

In some optional embodiments, as shown in FIG. 3, the encapsulation portion 401 is located at the side of the light-emitting unit 310 away from the base plate 100, the encapsulation portion 401 further covers a sidewall of the isolation structure 200 towards the isolation opening 240 and extends to a side of the isolation structure 200 away from the base plate 100, and at least one of the encapsulation portions 401 forms gaps with the encapsulation portion 401 adjacent to the at least one encapsulation portion 401 and the isolation structure 200, which may include at least one of the first gap Q1, the second gap Q2, the third gap Q3, or the first spacing Q4 as described above. Specifically, the second encapsulation layer 402 further fills at least a portion of the gaps, i.e., the second encapsulation layer 402 may fill any one, two, or three of the first gap Q1, the second gap Q2, the third gap Q3, and the first spacing Q4, or all of the first gap Q1, the second gap Q2, the third gap Q3, and the first spacing Q4, and may the first gap Q1. Alternatively, any one or more of the first gap Q1, the second gap Q2, the third gap Q3, and the first spacing Q4 are filled, but not completely filled.

Optionally, as shown in FIGS. 13 to 16, a portion of the second encapsulation layer 402 may be located in the first gap Q1 as described above, i.e., a portion of the second encapsulation layer 402 is located between the second segment 412 and the fourth segment 422, so as to ensure the stability of the relative position between the second segment 412 and the fourth segment 422.

Optionally, as shown in FIGS. 13 to 16, a portion of the second encapsulation layer 402 may be located in the second gap Q2 as described above, i.e., a portion of the second encapsulation layer 402 is located between the second segment 412 and the isolation structure 200, so as to ensure the stability of the relative position between the second segment 412 and the isolation structure 200.

Optionally, as shown in FIGS. 13 to 16, a portion of the second encapsulation layer 402 may be located in the third gap Q3 described above, i.e., a portion of the second encapsulation layer 402 may be located between the first sub-segment 422a of the fourth segment 422 and the isolation structure 200, so as to ensure the stability of the relative position between the first sub-segment 422a and the isolation structure 200.

Optionally, as shown in FIGS. 13 to 16, the display panel 10 further includes a third encapsulation layer 403 located at a side of the second encapsulation layer 402 away from the base plate 100.

Optionally, the second encapsulation layer 402 includes an organic material to have good thickness and flowability, and may flow to the first gap Q1, the second gap Q2, the third gap Q3, and the first spacing Q4 as described above.

Optionally, the third encapsulation layer 403 includes an inorganic material to have good compactness.

Optionally, the first encapsulation layer 400 includes an inorganic material to have good compactness.

In some optional embodiments, as shown in FIGS. 2 and 17, the isolation structure 200 includes a top surface 201 away from the base plate 100, the encapsulation portion 401 is located at a side of the light-emitting unit 310 away from the base plate 100, the encapsulation portion 401 further covers a sidewall of the isolation structure 200 towards the isolation opening 240 and extends to a side of the isolation structure 200 away from the base plate 240, and forms a covering segment 401a at the side of the isolation structure 200 away from the base plate 100; along a direction from the isolation opening 240 to an adjacent isolation opening 240, an orthographic projection of the top surface 201 on the base plate 100 has a first width D1, and an orthographic projection of the covering segment 401a located at a side of the top surface 201 away from the base plate 100 on the base plate 100 has a second width D2, that is, along a cross-section perpendicular to an extension direction of the isolation structure, the top surface has a first width D1, the covering segment located at a side of the top surface away from the base plate has a second width D2, and the first width D1 and the second width D2 satisfy:

$$\frac{1}{3} D 1 \leq D 2 \leq D 1.$$

In these optional embodiments, the orthographic projection of the top surface 201 of the isolation structure 200 on the base plate 100 has the first width D1, the orthographic projection of the covering segment 401a on the base plate 100 has the second width D2, and the first width D1 and the second width D2 satisfy

$$\frac{1}{3} D 1 \leq D 2 \leq D 1.$$

The second width D2 of the covering segment 401a is in this range, so that the encapsulation portion 401 is further lengthened with respect to the width in the related art, and when the second encapsulation layer 402 as described above is subsequently prepared, the contact area between the second encapsulation layer 402 and the encapsulation portion 401 is increased, thereby increasing the adhesion between the second encapsulation layer 402 and the encapsulation portion 401, reducing the possibility of film layer shedding and swelling of the second encapsulation layer 402 in a high-temperature and high-humidity environment, and increasing the using performance of the display panel 10.

Optionally, the covering segments 401a at the peripheries of the light-emitting units 310 emitting lights of a same color have the same second width D2. The encapsulation portions 401 corresponding to the light-emitting units 310 emitting lights of a same color can be prepared in a same process step, and if the second widths D2 corresponding to the light-emitting units 310 emitting lights of a same color are the same, the preparation of the encapsulation portions 401 corresponding to the light-emitting units 310 emitting lights of a same color can be simplified.

For example, if the light-emitting units 310 include the first light-emitting unit 311, the second light-emitting unit 312, and the third light-emitting unit 313 as described above, the covering segments 401a at the peripheries of the first light-emitting units 311 have the same second width D2, which can simplify the preparation of the encapsulation portions 401 corresponding to a plurality of first light-emitting units 311.

If the encapsulation portions 401 includes the first encapsulation portion 410, the second encapsulation portion 420, and the third encapsulation portion 430 as described above, the first encapsulation portion 410 includes the first segment 411 and the second segment 412, the second encapsulation portion 420 includes the third segment 421 and the fourth segment 422, and the third encapsulation portion 430 includes a fifth segment 431 and the sixth sub-segment 432, then the covering segment 401a of the first encapsulation portion 410 may be the second segment 412, the covering segment 401a of the second encapsulation portion 420 may be the fourth segment 422, and the covering segment 401a of the third encapsulation portion 430 may be the sixth segment 432.

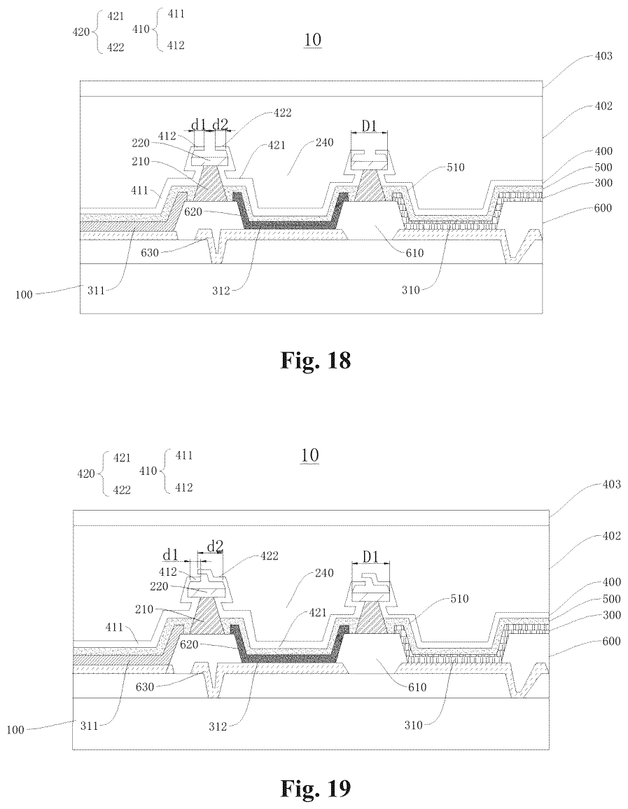

In some optional embodiments, as shown in FIGS. 2, 18, and 19, the width of the second segment 412 is a first sub-width d1, and the width of the fourth segment 422 close to the first light-emitting unit 311 is a second sub-width d2. That is, along a cross-section perpendicular to an extension direction of the isolation structure 200 between the first light-emitting unit 311 and the second light-emitting unit 312, for the second segment 412 and the fourth segment 422 that are located on a same isolation structure 200 or the second segment 412 and the fourth segment 422 that overlap, the width of the second segment 412 is the first sub-width d1 and the width of the fourth segment 422 is the second sub-width d2. Herein, the first sub-width d1 and the second sub-width d2 satisfy:

d1≤d2.

In these optional embodiments, for the encapsulation portion 401 located at the side of the second light-emitting unit 312 away from the base plate 100, the second sub-width d2 of a portion of the fourth segment 422 is greater than or equal to the first sub-width d1 of the second segment 412. That is, the fourth segment 422 of the encapsulation portion 401 located at the side of the second light-emitting unit 312 away from the base plate 100 is further lengthened at a side close to the first light-emitting unit 311, which increases the contact area between the encapsulation portion 401 located at the side of the second light-emitting unit 312 away from the base plate 100 and the second encapsulation layer 402, thereby increasing the adhesion between the second segment 412 corresponding to the second light-emitting unit 312 and the second encapsulation layer 402.

Optionally, the first sub-width d1 and the first width D1 satisfy:

$$\frac{1}{3} D 1 \leq d 1 \leq \frac{1}{2} D 1.$$

In these optional embodiments, the first sub-width d1 is greater than or equal to one-third of the first width D1, which can avoid the first sub-width d1 and the contact area between the second segment 412 and the second encapsulation layer 402 being too less, and the adhesion being low, which otherwise causes film layer shedding and swelling of the second encapsulation layer 402 in a high-temperature and high-humidity environment. The first sub-width d1 is less than or equal to one-half of the first width D1, which can avoid the first sub-width d1 being too great. If the first sub-width d1 is too great, when the second encapsulation portion 420 and the third encapsulation portion 430 are subsequently prepared, the fourth segment 422 or the sixth segment 432 is more likely to be located at a side of the second segment 412 corresponding to the first light-emitting unit 311 away from the base plate 100, and a majority of the fourth segment 422 or the sixth segment 432 is far away from the isolation structure 200, which causes film layer shedding of the fourth segment 422 or the sixth segment 432 under external impact.

Optionally, the second light-emitting unit 312 as described above may be located between the first light-emitting unit 311 and the third light-emitting unit 313.

Optionally, the second sub-width d2 and the first width D1 satisfy:

$$\frac{1}{3} D 1 \leq d 2 \leq \frac{1}{2} D 1 or \frac{1}{2} D 1 \leq d 2 \leq D 1.$$

In these optional embodiments, the second sub-width d2 is greater than or equal to one-third of the first width D1, which can avoid the second sub-width d2 and the contact area between the fourth segment 422 and the second encapsulation layer 402 being too less, and the adhesion being low, which otherwise causes film layer shedding and swelling of the second encapsulation layer 402 in a high-temperature and high-humidity environment. The second sub-width d2 is greater than or equal to one-half of the first width D1, that is the fourth segment 422 is further lengthened at a side close to the first light-emitting unit 311, which increases the contact area between the encapsulation portion 401 located at the side of the second light-emitting unit 312 away from the base plate 100 and the second encapsulation layer 402, thereby increasing the adhesion between the second encapsulation layer 402 and the fourth segment 422.

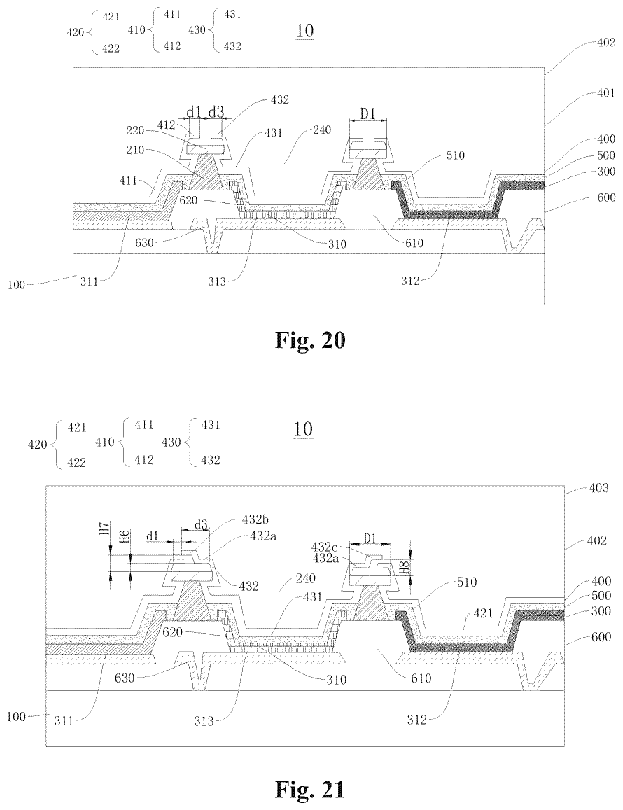

Optionally, as shown in FIGS. 2, 20, and 21, the second width D2 of the second segment 412 is a first sub-width d1, i.e., the width of the sixth segment 432 close to the first light-emitting unit 311 is a third sub-width d3. That is, along a cross-section perpendicular to an extension direction of the isolation structure 200 between the first light-emitting unit 311 and the third light-emitting unit 312, for the second segment 412 and the sixth segment 432 that are located on a same isolation structure 200 or the second segment 412 and the sixth segment 432 that overlap, the width of the second segment 412 is the first sub-width d1 and the width of the sixth segment 432 is the third sub-width d3. Herein, the first sub-width d1 and the third sub-width d3 satisfy:

d1≤d3.

In these optional embodiments, the third sub-width d3 of the sixth segment 432 is greater than or equal to the first sub-width d1 of the second segment 412, i.e., the sixth segment 432 is further lengthened at a side close to the first light-emitting unit 311, which increases the contact area between the third encapsulation portion 430 and the second encapsulation layer 402, thereby increasing the adhesion between the second encapsulation layer 402 and the sixth segment 432.

Optionally, the third sub-width d3 and the first width D1 satisfy:

$$\frac{1}{3} D 1 \leq d 3 \leq \frac{1}{2} D 1 or \frac{1}{2} D 1 \leq d 3 \leq D 1.$$

In these optional embodiments, the third sub-width d3 is greater than or equal to one-third of the first width D1, which can avoid the third sub-width d3 and the contact area between the sixth segment 432 and the second encapsulation layer 402 being too less, and the adhesion being low, which otherwise causes film layer shedding and swelling of the second encapsulation layer 402 in a high-temperature and high-humidity environment. The third sub-width d3 is greater than or equal to one-half of the first width D1, that is the sixth segment 432 is further lengthened at a side close to the first light-emitting unit 311, which increases the contact area between the third encapsulation portion 430 and the second encapsulation layer 402, thereby increasing the adhesion between the second encapsulation layer 402 and the sixth segment 432.

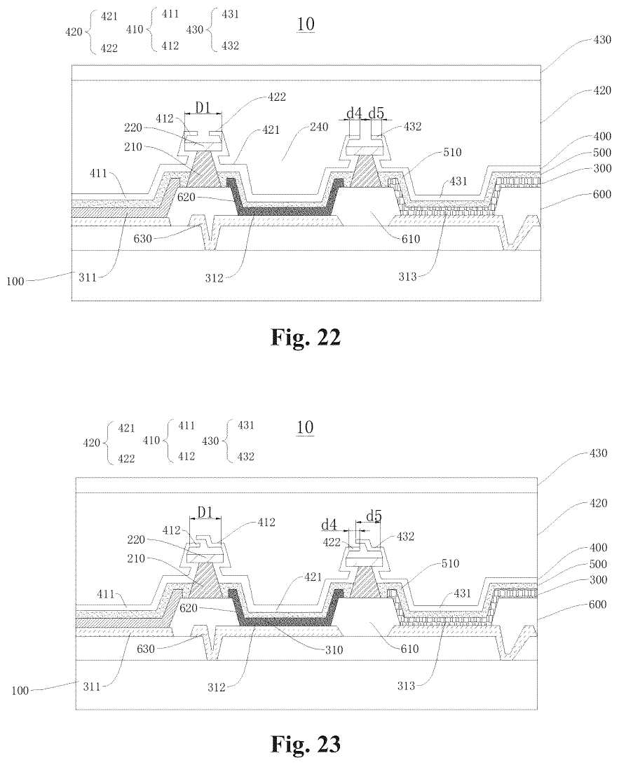

Optionally, as shown in FIGS. 2, 22, and 23, the second width D2 of the fourth segment 422 close to the third light-emitting unit 313 is a fourth sub-width d4, and the second width D2 of the sixth segment 432 close to the second light-emitting unit 312 is a fifth sub-width d5. That is, along a cross-section perpendicular to an extension direction of the isolation structure 200 between the second light-emitting unit 312 and the third light-emitting unit 313, for the fourth segment 422 and the sixth segment 432 that are located on a same isolation structure 200 or the fourth segment 422 and the sixth segment 432 that overlap, the width of the fourth segment 422 is the fourth sub-width d4 and the width of the sixth segment 432 is the fifth sub-width d5. Herein, the fourth sub-width d4 and the fifth sub-width d5 satisfy:

d4≤d5.

In these optional embodiments, the fifth sub-width d5 is greater than or equal to the fourth sub-width d4, i.e., the sixth segment 432 is further lengthened at a side close to the second light-emitting unit 312, which increases the contact area between the third encapsulation portion 430 and the second encapsulation layer 402, thereby increasing the adhesion between the second encapsulation layer 402 and the third encapsulation portion 430.

Optionally, the fourth sub-width d4 and the first width D1 satisfy:

$$\frac{1}{3} D 1 \leq d 4 \leq \frac{1}{2} D 1.$$

In these optional embodiments, the fourth sub-width d4 is greater than or equal to one-third of the first width D1, which can avoid the fourth sub-width d4 and the contact area between the fourth segment 422 and the second encapsulation layer 402 being too less, and the adhesion being low, which otherwise causes film layer shedding and swelling of the second encapsulation layer 402 in a high-temperature and high-humidity environment. The fourth sub-width d4 is less than or equal to one-half of the first width D1, which can avoid the fourth sub-width d4 being too great, otherwise when the third encapsulation portion 430 is subsequently prepared, the sixth segment 432 is more likely to be located at a side of the second segment 412 corresponding to the second light-emitting unit 312 away from the base plate 100, and a majority of the sixth segment 432 is far away from the isolation structure 200, which causes film layer shedding of the sixth segment 432 under external impact.

Optionally, the fifth sub-width d5 and the first width D1 satisfy:

$$\frac{1}{3} D 1 \leq d 5 \leq \frac{1}{2} D 1 or \frac{1}{2} D 1 \leq d 5 \leq D 1.$$

In these optional embodiments, the fifth sub-width d5 is greater than or equal to one-third of the first width D1, which can avoid the fifth sub-width d5 and the contact area between the sixth segment 432 and the second encapsulation layer 402 being too less, and the adhesion being low, which otherwise causes film layer shedding and swelling of the second encapsulation layer 402 in a high-temperature and high-humidity environment. The fifth sub-width d5 is greater than or equal to one-half of the first width D1, that is the sixth segment 432 is further lengthened at a side close to the first light-emitting unit 311, which increases the contact area between the sixth segment 432 and the second encapsulation layer 402, thereby increasing the adhesion between the second encapsulation layer 402 and the sixth segment 432.

In some optional embodiments, as shown in FIGS. 3 and 4, the isolation structure 200 includes a first layer 210 and a second layer 220 located at a side of the first layer 210 away from the base plate 100, and an orthographic projection of the first layer 210 on the base plate 100 is located within an orthographic projection of the second layer 220 on the base plate 100.

In these optional embodiments, the first layer 210 and the second layer 220 are provided to form the isolation structure 200, the orthographic projection of the first layer 210 arranged close to the base plate 100 on the base plate 100 is located within the orthographic projection of the second layer 220 on the base plate 100, the area of the second layer 220 is greater than the area of the first layer 210, the second layer 220 covers a surface of the first layer 210 close to the second layer 220, in which case the first layer 210 is recessed relative to the second layer 220 in a direction away from the isolation opening 240. In preparing the light-emitting layer 300, the light-emitting layer 300 generates a large drop at the edge of the isolation structure 200, and the first layer 210 is concave with respect to the second layer 220, it is difficult for the light-emitting layer 300 to be connected at the edge of the isolation structure 200 and thus fracture occurs, and the light-emitting layer 300 is fractured to form the light-emitting units 310 that are disconnected from each other.

Optionally, the orthographic projection of the first layer 210 on the base plate 100 is smaller than the orthographic projection of the second layer 220 on the base plate 100, so as to form a concave under the second layer 220.

Optionally, the first layer 210 includes a conductive material, and the second electrode 510 may be connected to the first layer 210, so that a plurality of the second electrodes 510 may be interconnected by the isolation structure 200 as a planar electrode.

Optionally, the second layer 220 includes a conductive material or an insulating material.

Optionally, the first layer 210 and the second layer 220 each include a metal material, and the materials of the first layer 210 and the second layer 220 are different, which facilitates preparing the first layer 210 and the second layer 220 of different sizes according to the different etching rates of the first layer 210 and the second layer 220.

Optionally, as shown in FIGS. 10, 12 to 16, the isolation structure 200 further comprises a third layer 230 located at a side of the first layer 210 towards the base plate 100, and the orthographic projection of the first layer 210 on the base plate 100 is located within the orthographic projection of the third layer 230 on the base plate 100. The third layer 230 may provide protection to the film layers at the side towards the base plate 100 when the first layer 210 is side-etched.

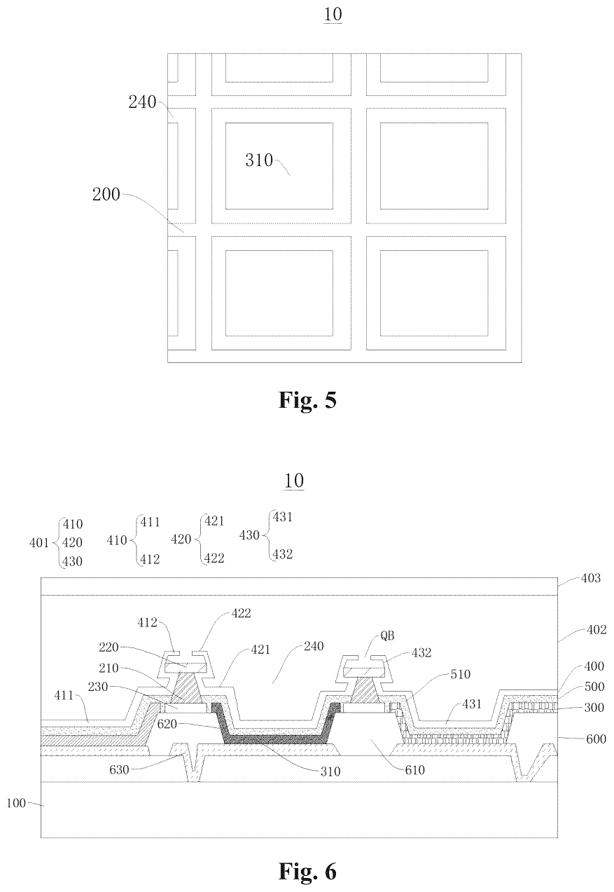

As shown in FIGS. 1 to 23, another embodiment of the first aspect of the present application further provides a display panel 10, including: a base plate 100; an isolation structure 200 located at one side of the base plate 100 and including a top surface 201 away from the base plate 100; a plurality of isolation openings 240 encircled by the isolation structure 200; a light-emitting layer 300 located at one side of the base plate 100 and including a plurality of light-emitting units 310, the plurality of light-emitting units 310 being at least partially located in the plurality of isolation openings 240, respectively; and a first encapsulation layer 400 including a plurality of encapsulation portions 401 for encapsulating the plurality of light-emitting units 310, in which the plurality of encapsulation portions 401 are located at a side of the plurality of light-emitting units 310 away from the base plate 100, the plurality of encapsulation portions 401 further cover a sidewall of the isolation structure 200 towards the plurality of isolation openings 240 and extend to a side of the isolation structure 200 away from the base plate 100, and form a plurality of covering segments 401a at the side of the isolation structure 200 away from the base plate 100, the covering segment 401a of at least one of the plurality of encapsulation portions 401 includes a first area and a second area, and along a thickness direction Z of the base plate 100, a distance from the first area to the top surface 201 is different from a distance from the second area to the top surface 201.

In these optional embodiments, the display panel 10 includes the base plate 100, the isolation structure 200, the isolation openings 240, the light-emitting layer 300, and the first encapsulation layer 400. The isolation structure 200 is arranged on the base plate 100 and encircles the plurality of isolation openings 240, so as to separate the light-emitting layer 300 to form the light-emitting units 310 that are disconnected from each other, thereby reducing the crosstalk of carriers in the light-emitting layer 300 and improving the display effect of the display panel 10, and the light-emitting units 310 are prepared without a fine mask plate, which can reduce the development and use of the fine mask plate and reduce the preparation cost. The covering segment 401a of the encapsulation portion 401 includes the first area and the second area, and as shown in FIG. 9, the first area and the second area are located at different sides of the periphery the light-emitting unit 310, and the heights of the first area and the second area with respect to the base plate 100 are different, which facilitates the first area and the second area overlapping the encapsulation portions 401 corresponding to different light-emitting units 310 while the covering segment 401a overlaps other encapsulation portions 401.

In some optional embodiments, as shown in FIGS. 2 and 3, the orthographic projections of the covering segments 401a of the encapsulation portions 401 corresponding to at least a portion of the light-emitting units 310 on the base plate 100 at least partially overlap, which can reduce the encapsulation failure of the encapsulation portion 401 that is covered.

As described above, optionally, the light-emitting units 310 include a plurality of first light-emitting units 311, a plurality of second light-emitting units 312, and a plurality of third light-emitting units 313 of different colors, and the encapsulation portions 401 include a plurality of first encapsulation portions 410 for encapsulating the plurality of first light-emitting units 311, a plurality of second encapsulation portions 420 for encapsulating the plurality of second light-emitting units 312, and a plurality of third encapsulation portions 430 for encapsulating the plurality of third light-emitting units 313. The first encapsulation portion 410 includes a first segment 411 and a second segment 412, the second encapsulation portion 420 includes a third segment 421 and a fourth segment 422, and the third encapsulation portion 430 includes a fifth segment 431 and a sixth segment 432. The second segment, the fourth segment, and the sixth segment are the covering segments 401a of the first encapsulation portion 410, the second encapsulation portion 420, and the third encapsulation portion 430, respectively.

Optionally, the first light-emitting unit 311 and the second light-emitting unit 312 are arranged adjacently, and at least a portion of the fourth segment 422 may extend to the side of the second segment 412 away from the base plate 100, i.e., a portion of the fourth segment 422 covers the second segment 412.

Optionally, as shown in FIGS. 12 and 13, the distances from at least two areas in the second segment 412 of a same first encapsulation portion 410 to the top surface 201 are the same. For example, if the first encapsulation portion 410 is prepared prior to the second encapsulation portion 420 and the third encapsulation portion 430, the second gap Q2 as described above is between the second segment 412 of the first encapsulation portion 410 and the isolation structure 200 and formed by removing the first light-emitting material layer and the first conductive material layer located at this location, and thus the distances from at least two areas in the second segment 412 of a same first encapsulation portion 410 to the top surface 201 are the same.

Optionally, as shown in FIGS. 2, 13, and 14, as described above, the fourth segment 422 may include a first sub-segment 422a and a second sub-segment 422b, the second sub-segment 422b extends to the side of the second segment away from the base plate, the first sub-segment 422a and the second sub-segment 422b form the first area and the second area of the second encapsulated portion, respectively, and a distance between the first sub-segment 422a and the top surface 201 along a thickness direction Z of the display panel 10 is different from a distance between the second sub-segment 422b and the top surface 201 along the thickness direction Z of the display panel 10. Since the second sub-segment 422b covers the second segment 412, while the first sub-segment 422a is side by side with the second segment 412, the distances from the first sub-segment 422a and the second sub-segment 422b to the top surface 201 are different. Moreover, the distance between the first sub-segment 422a and the top surface 201 along the thickness direction Z of the display panel 10 is less than the distance between the second sub-segment 422b and the top surface 201 along the thickness direction Z of the display panel 10.

Optionally, as shown in FIG. 12, as described above, the third light-emitting unit is further arranged adjacent to at least one of the first light-emitting unit and the second light-emitting unit, and if the third encapsulation portion 430 includes a fifth segment 431 and a sixth segment 432, an orthographic projection of the sixth segment 432 on the base plate 100 overlaps at least one of the orthographic projections of the second segment 412 and the fourth segment 422 on the base plate 100. For example, the sixth segment 432 further at least partially extends to a side of the second segment 412 or the fourth segment 422 away from the base plate 100.

Optionally, as shown in FIG. 21, the sixth segment 432 includes a third sub-segment 432a and a fourth sub-segment 432b, the third sub-segment 432a is connected between the fifth segment 431 and the fourth sub-segment 432b, the fourth sub-segment 432b is located at a side of the second segment 412 away from the base plate 100, the third sub-segment 432a and the fourth sub-segment 432b form the first area and the second area of the third encapsulation portion, respectively, and a distance H6 between the third sub-segment 432a and the top surface 201 along a thickness direction Z of the display panel 10 is different from a distance H7 between the fourth sub-segment 432b and the top surface 201 along the thickness direction Z of the display panel 10.

In these optional embodiments, since the fourth sub-segment 432b covers the second segment 412, the distance H6 between the third sub-segment 432a and the top surface 201 along the thickness direction Z of the display panel 10 is different from the distance H7 between the fourth sub-segment 432b and the top surface 201 along the thickness direction Z of the display panel 10.

Optionally, as shown in FIG. 21, the sixth segment 432 includes a third sub-segment 432a and a fifth sub-segment 432c, the third sub-segment 432a is connected between the fifth segment 431 and the fifth sub-segment 432c, the fifth sub-segment 432c is located at a side of the fourth segment 422 away from the base plate 100, the third sub-segment 432a and the fifth sub-segment 432c form the first area and the second area of the third encapsulation portion, respectively, and a distance H6 between the third sub-segment 432a and the top surface 201 along a thickness direction Z of the display panel 10 is different from a distance H8 between the fifth sub-segment 432c and the top surface 201 along the thickness direction Z of the display panel 100. Since the fifth sub-segment 432c covers the third segment 421, the distance H6 between the third sub-segment 432a and the top surface 201 along the thickness direction Z of the display panel 10 is different from the distance H8 between the fifth sub-segment 432c and the top surface 201 along the thickness direction Z of the display panel 100.

Optionally, as shown in FIG. 9, the orthographic projections of the first area and the second area of a same encapsulation portion on the base plate 100 at lease partially overlap the orthographic projections of the encapsulation portions 401 corresponding to the light-emitting units 310 of different colors on the base plate 100.

In these optional embodiments, the encapsulation portions 401 corresponding to the light-emitting units 310 of a same color may be prepared in a same process step, the encapsulation portions 401 corresponding to the light-emitting units 310 of different colors may be prepared in different process steps, and the first area and the second area may overlap the encapsulation portions 401 prepared in different steps, respectively.

Optionally, as shown in FIG. 21, the sixth segment 432 includes a third sub-segment 432a connected with the fifth segment 431 and a fourth sub-segment 432b and a fifth sub-segment 432c connected with the third sub-segment 432a, and the fourth sub-segment 432b and the fifth sub-segment 432c are arranged in sequence along a periphery of the third sub-segment 432a; the fourth sub-segment 432b is located at a side of the second segment 412 away from the base plate 100, the fifth sub-segment 432c is located at a side of the fourth segment 422 away from the base plate 100, any two of the third sub-segment 432a, the fourth sub-segment 432b, and the fifth sub-segment 432c form the first area and the second area of the third encapsulation portion, respectively, and at least two of a distance H6 between the third sub-segment 432a and the top surface 201 along the thickness direction Z of the display panel 10, a distance H7 between the fourth sub-segment 432b and the top surface 201 along the thickness direction Z of the display panel 10, and a distance H8 between the fifth sub-segment 432c and the top surface 201 along the thickness direction Z of the display panel 10 are different. The fourth sub-segment 432b is located at the side of the second segment 412 away from the base plate 100, and the fifth sub-segment 432c is located at the side of the fourth segment 422 away from the base plate 100, i.e., the fourth sub-segment 432b of the third encapsulation portion covers a portion of the first encapsulation portion, and the fifth sub-segment 432c of the third encapsulation portion covers a portion of the second encapsulation portion, and thus at least two of the distance H6 between the third sub-segment 432a and the top surface 201 along the thickness direction Z of the display panel 10, the distance H7 between the fourth sub-segment 432b and the top surface 201 along the thickness direction Z of the display panel 10, and the distance H8 between the fifth sub-segment 432c and the top surface 201 along the thickness direction Z of the display panel 10 are different.

The embodiments of the second aspect of the present application further provide a display apparatus including the display panel 10 of any of the above embodiments of the first aspect. Since the display apparatus according to the embodiments of the second aspect of the present application includes the display panel 10 of any of the above embodiments of the first aspect, the display apparatus according to the embodiments of the second aspect of the present application has the beneficial effects of the display panel 10 of any of the above embodiments of the first aspect, which will not be repeated herein.

The display apparatus in the embodiments of the present application includes, but is not limited to, a cellular phone, a Personal Digital Assistant (PDA), a tablet computer, an e-book, a TV, an entrance guard, an intelligent landline phone, a console, and other devices with display function.

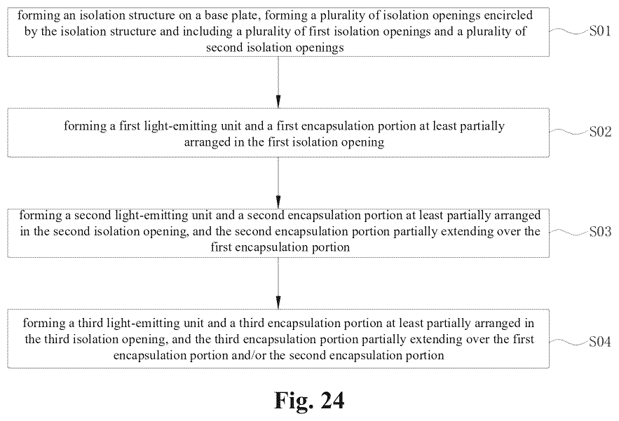

The embodiments of the third aspect of the present application provide a method for manufacturing a display panel, referring to FIGS. 1 to 23 and 24, the method includes:
step S01: forming an isolation structure 200 on a base plate, forming a plurality of isolation openings 240 encircled by the isolation structure 20 and including a plurality of first isolation openings and a plurality of second isolation openings;
step S02: forming a first light-emitting unit 311 and a first encapsulation portion 410 at least partially arranged in the first isolation opening; and
step S03: forming a second light-emitting unit 312 and a second encapsulation portion 420 at least partially arranged in the second isolation opening, and the second encapsulation portion 420 partially extending over the first encapsulation portion 410.

In the embodiments of the present application, the isolation structure 200 and the isolation openings are first prepared, then the first light-emitting unit 311 and the first encapsulation portion 410, and then the second light-emitting unit 312 and the second encapsulation portion 420. The second encapsulation portion 420 is prepared after the first encapsulation portion 410, and the preparation material of the second encapsulation portion 420 may entirely cover the first encapsulation portion 410. In patterning the preparation material to form the second encapsulation portion 420, a portion of the material located on the first encapsulation portion 410 is retained so that the second encapsulation portion 420 partially extends over the first encapsulation portion 410, and this portion of the second encapsulation portion 420 may provide protection to the first encapsulation portion 410 and reduce the possibility of damage to the first encapsulation portion 410 that is covered.

In some optional embodiments, after step S03, the method may further include:
step S04: forming a third light-emitting unit 313 and a third encapsulation portion 430 at least partially arranged in the third isolation opening, and the third encapsulation portion 430 partially extending over the first encapsulation portion 410 or the second encapsulation portion 420.

In the embodiments of the present application, the third encapsulation portion 430 is prepared after the first encapsulation portion 410 and the second encapsulation portion 420, and the preparation material of the third encapsulation portion 430 may entirely cover the first encapsulation portion 410 and the second encapsulation portion 420. In patterning the preparation material to form the third encapsulation portion 430, a portion of the material located on the first encapsulation portion 410 or the second encapsulation portion 420 is retained so that the third encapsulation portion 430 partially extends over the first encapsulation portion 410 or the second encapsulation portion 420, and this portion of the third encapsulation portion 430 may provide protection to the first encapsulation portion 410 or the second encapsulation portion 420 and reduce the possibility of damage to the first encapsulation portion 410 or the second encapsulation portion 420 that is covered.

According to the above embodiments of the present application, these embodiments do not exhaustively describe all the details, nor do they limit the present application to the specific embodiments only. Obviously, many modifications and variations may be made in accordance with the above description. These embodiments are selected and specifically described in the specification for better explaining the principles and practical applications of the present application, so that those skilled in the art can make good use of the present application and make modifications on the basis of the present application. The present application is limited only by the claims and their full scope and equivalents.

What is claimed is:

1. A display panel comprising:
a base plate;
an isolation structure located at one side of the base plate;
a plurality of isolation openings encircled by the isolation structure;
a light-emitting layer located at one side of the base plate and comprising a plurality of light-emitting units arranged at intervals, the plurality of light-emitting units being at least partially located in the plurality of isolation openings, respectively; and
a first encapsulation layer comprising a plurality of encapsulation portions for encapsulating the plurality of light-emitting units,
wherein an orthographic projection of an encapsulation portion corresponding to at least one of the plurality of light-emitting units on the base plate at least partially overlaps an orthographic projection of an encapsulation portion corresponding to at least one of the light-emitting units adjacent to the at least one light-emitting unit on the base plate.

2. The display panel according to claim 1, wherein orthographic projections of a plurality of adjacent encapsulation portions on the base plate encircle a plurality of hollow areas located within an orthographic projection of the isolation structure on the base plate.

3. The display panel according to claim 2, wherein an orthographic projection of an encapsulation portion corresponding to one of the plurality of light-emitting units on the base plate overlaps orthographic projections of the encapsulation portions corresponding to a portion of the light-emitting units adjacent to the light-emitting unit on the base plate.

4. The display panel according to claim 2, wherein one of the plurality of light-emitting units is adjacent to N light-emitting units at a periphery of the light-emitting unit, an orthographic projection of an encapsulation portion corresponding to the light-emitting unit on the base plate overlaps orthographic projections of the encapsulation portions corresponding to M light-emitting units adjacent to the light-emitting unit at the periphery of the light-emitting unit on the base plate, and M<N.

5. The display panel according to claim 2, wherein the isolation structure is further provided with a plurality of light-transmitting openings, and an orthographic projection of the light-transmitting opening on the base plate at least partially overlaps an orthographic projection of the hollow area on the base plate.

6. The display panel according to claim 1, wherein orthographic projections of the plurality of encapsulation portions corresponding to a plurality of adjacent light-emitting units on the base plate completely cover an orthographic projection of the isolation structure between the plurality of adjacent light-emitting units on the base plate.

7. The display panel according to claim 6, wherein orthographic projections of the encapsulation portions corresponding to any adjacent two of the plurality of light-emitting units on the base plate at least partially overlap.

8. The display panel according to claim 1, wherein the plurality of light-emitting units comprise a plurality of first light-emitting units and a plurality of second light-emitting units arranged adjacently; and
the encapsulation portion is located at a side of the light-emitting unit away from the base plate, and the encapsulation portion further covers a sidewall of the isolation structure towards the isolation opening and extends to a side of the isolation structure away from the base plate; the plurality of encapsulation portions comprise a plurality of first encapsulation portions for encapsulating the plurality of first light-emitting units and a plurality of second encapsulation portions for encapsulating the plurality of second light-emitting units, and at least a portion of the plurality of second encapsulation portions further extends to a side of the first encapsulation portion away from the base plate.

9. The display panel according to claim 8, wherein the first encapsulation portion comprises a first segment and a second segment connected to each other, the first segment is located at a side of the first light-emitting unit away from the base plate and covers the sidewall of the isolation structure towards the isolation opening, and the second segment is located at the side of the isolation structure away from the base plate; and
the second encapsulation portion comprises a third segment and a fourth segment connected to each other, the third segment is located at a side of the second light-emitting unit away from the base plate and covers the sidewall of the isolation structure towards the isolation opening, and the fourth segment is located at the side of the isolation structure away from the base plate;
wherein at least a portion of the fourth segment extends to a side of the second segment away from the base plate.

10. The display panel according to claim 9, wherein the fourth segment comprises a first sub-segment and a second sub-segment, the first sub-segment is connected between the third segment and the second sub-segment, the second sub-segment is arranged around a portion of the first sub-segment, and the second sub-segment is located at the side of the second segment away from the base plate.

11. The display panel according to claim 9, wherein along a thickness direction of the display panel, a plurality of redundant electrodes are provided between at least a portion of the plurality of fourth segments and the isolation structure.

12. The display panel according to claim 11, wherein the fourth segment comprises a first sub-segment and a second sub-segment, the first sub-segment is connected between the third segment and the second sub-segment, the second sub-segment is located at the side of the second segment away from the base plate, and the first sub-segment and the isolation structure are spaced apart along the thickness direction of the display panel and form a third gap; the redundant electrode is located in the third gap.

13. The display panel according to claim 9, wherein at least a portion of the plurality of second segments and at least a portion of the plurality of fourth segments are spaced apart.

14. The display panel according to claim 13, wherein the fourth segment comprises a first sub-segment and a second sub-segment, the second sub-segment is arranged around a portion of the first sub-segment, and the second sub-segment is located at the side of the second segment away from the base plate; the first sub-segment comprises a first body portion and a connecting portion, the first body portion is connected to the third segment, the connecting portion is connected between the first body portion and the second sub-segment, and an orthographic projection of the first body portion on the base plate is spaced apart from an orthographic projection of the second segment on the base plate.

15. The display panel according to claim 14, wherein the second segment comprises a first surface and a second surface arranged opposite to each other in a thickness direction of the display panel, the first surface is arranged towards the base plate, the second surface is arranged away from the base plate, the second segment further comprises a first side surface connecting the first surface and the second surface, and a first spacing is formed between the connecting portion and the first side surface.

16. The display panel according to claim 15, wherein the second sub-segment and the second segment are spaced apart along the thickness direction of the display panel and form a first gap, and a size of the first spacing along a normal direction of the first side surface is less than a size of the first gap along the thickness direction of the display panel.

17. The display panel according to claim 9, wherein at least a portion of the plurality of second segments and at least a portion of the plurality of fourth segments are interconnected.

18. The display panel according to claim 17, wherein the second segment comprises a first surface and a second surface arranged opposite to each other in a thickness direction of the display panel, the first surface is arranged towards the base plate, the second surface is arranged away from the base plate, the second segment further comprises a first side surface connecting the first surface and the second surface, and the fourth segment and the first side surface are interconnected.

19. The display panel according to claim 1, wherein an orthographic projection of an encapsulation portion corresponding to one of the plurality of light-emitting units on the base plate and an orthographic projection of an encapsulation portion corresponding to at least one of the light-emitting units adjacent to the one of the plurality of light-emitting units on the base plate at least partially overlap and form an overlapping area, the isolation structure comprises a top surface away from the base plate, and an area of the overlapping area is in the range of 15% to 75% of an area of an orthographic projection of the top surface on the base plate.

20. A display panel comprising:
a base plate;
an isolation structure located at one side of the base plate and comprising a top surface away from the base plate;
a plurality of isolation openings encircled by the isolation structure;
a light-emitting layer located at one side of the base plate and comprising a plurality of light-emitting units, the plurality of light-emitting units being at least partially located in the plurality of isolation openings, respectively; and
a first encapsulation layer comprising a plurality of encapsulation portions for encapsulating the plurality of light-emitting units,
wherein the plurality of encapsulation portions are located at a side of the plurality of light-emitting units away from the base plate, the plurality of encapsulation portions further cover a sidewall of the isolation structure towards the plurality of isolation openings and extend to a side of the isolation structure away from the base plate, and form a plurality of covering segments at the side of the isolation structure away from the base plate, the covering segment of at least one of the plurality of encapsulation portions comprises a first area and a second area, and along a thickness direction of the base plate, a distance from the first area to the top surface is different from a distance from the second area to the top surface.

21. The display panel according to claim 20, wherein orthographic projections of covering segments of the encapsulation portions corresponding to at least a portion of the plurality of light-emitting units on the base plate at least partially overlap.

22. The display panel according to claim 21, wherein the plurality of light-emitting units comprise a plurality of first light-emitting units and a plurality of second light-emitting units that are adjacent, the plurality of encapsulation portions comprise a plurality of first encapsulation portions for encapsulating the plurality of first light-emitting units and a plurality of second encapsulation portions for encapsulating the plurality of second light-emitting units, the covering segment comprises a second segment in the first encapsulation portion located at a side of the isolation structure away from the base plate and a fourth segment in the second encapsulation portion located at the side of the isolation structure away from the base plate, and orthographic projections of the second segment and the fourth segment on the base plate at least partially overlap.

23. The display panel according to claim 22, wherein distances from at least two areas in the second segment of a same first encapsulation portion to the top surface are the same.

24. The display panel according to claim 22, wherein the second encapsulation portion further comprises a third segment and a fourth segment, the third segment is located at a side of the second light-emitting unit away from the base plate and covers the sidewall of the isolation structure towards the isolation opening, the fourth segment comprises a first sub-segment and a second sub-segment, the first sub-segment is connected between the third segment and the second sub-segment, the second sub-segment is located at a side of the second segment away from the base plate, and a distance between the first sub-segment and the top surface along a thickness direction of the display panel is different from a distance between the second sub-segment and the top surface along the thickness direction of the display panel.

25. The display panel according to claim 24, wherein the distance between the first sub-segment and the top surface along the thickness direction of the display panel is less than the distance between the second sub-segment and the top surface along the thickness direction of the display panel.

26. The display panel according to claim 22, wherein the plurality of light-emitting units further comprise a plurality of third light-emitting units arranged adjacent to at least one of the plurality of first light-emitting units and the plurality of second light-emitting units, the plurality of encapsulation portions comprise a plurality of third encapsulation portions for encapsulating the plurality of third light-emitting units, the covering segment comprises a sixth segment in the third encapsulation portion located at the side of the isolation structure away from the base plate, and an orthographic projection of the sixth segment on the base plate overlaps at least one of orthographic projections of the second segment and the fourth segment on the base plate.

27. The display panel according to claim 26, wherein the sixth segment further at least partially extends to a side of the second segment or the fourth segment away from the base plate.

28. A display apparatus comprising the display panel according to claim 1.

29. A method for manufacturing a display panel, comprising:
forming an isolation structure on a base plate;
forming a plurality of isolation openings encircled by the isolation structure and comprising a plurality of first isolation openings and a plurality of second isolation openings;
forming a plurality of first light-emitting units and a plurality of first encapsulation portions at least partially arranged in the plurality of first isolation openings, respectively; and
forming a plurality of second light-emitting units and a plurality of second encapsulation portions at least partially arranged in the plurality of second isolation openings, respectively, and the plurality of second encapsulation portions partially extending over the plurality of first encapsulation portions.

30. The method according to claim 29, wherein the plurality of isolation openings further comprises a plurality of third isolation openings, the method further comprises:
forming a plurality of third light-emitting units and a plurality of third encapsulation portions at least partially arranged in the plurality of third isolation openings, and the third encapsulation portion partially extending over the first encapsulation portion or the second encapsulation portion.
